(19) United States
(12) Patent Application Publication
(10) Pub. No.: US 2026/0173363 A1
(43) Pub. Date: Jun. 18, 2026

(54) SEMICONDUCTOR DEVICE

(71) Applicant: Samsung Electronics Co., Ltd., Suwon-si (KR)

(72) Inventors: Jaehyeok BAEK, Suwon-si (KR); GILYOUNG KANG, Suwon-si (KR); HYE-RAN KIM, Suwon-si (KR); Junsoo YEO, Suwon-si (KR); SungYong CHO, Suwon-si (KR)

(21) Appl. No.: 19/251,558

(22) Filed: Jun. 26, 2025

(30) Foreign Application Priority Data
Dec. 13, 2024 (KR) 10-2024-0186036

(51) Int. Cl. H10B 12/00

(52) U.S. Cl. CPC H10B 12/50; H10B 12/315; H10B 12/482; H10B 12/485

(57) ABSTRACT

A semiconductor device may include a substrate including a cell block region and a peripheral region, a memory cell array on the cell block region, and a peripheral capacitor structure on the peripheral region. The peripheral capacitor structure may include a first lower peripheral electrode placed at a level lower than the cell conductive structure, a second lower peripheral electrode spaced apart from the first lower peripheral electrode, a first upper peripheral electrode placed at a level higher than the first and second lower peripheral electrodes, and a second upper peripheral electrode spaced apart from the first upper peripheral electrode.

### CROSS-REFERENCE TO RELATED APPLICATIONS

This U.S. non-provisional patent application claims priority under 35 U.S.C. § 119 to Korean Patent Application No. 10-2024-0186036, filed on Dec. 13, 2024, in the Korean Intellectual Property Office, the entire contents of which are hereby incorporated by reference.

### BACKGROUND OF THE INVENTION

The present disclosure relates to a semiconductor device, and in particular, to a semiconductor device including a peripheral capacitor structure.

Due to their small-sized, multifunctional, and/or low-cost characteristics, semiconductor devices are being esteemed as important elements in the electronics industry. The semiconductor devices are classified into semiconductor memory devices for storing data, semiconductor logic devices for processing data, and hybrid semiconductor devices including both of memory and logic elements.

With the recent trend of high speed and low power consumption of electronic devices, semiconductor devices in the electronic devices are generally required to have high operating speeds and/or low operating voltages, and in order to satisfy these requirements, it is advantageous to increase an integration density of the semiconductor devices. However, as the integration density of the semiconductor devices increases, the semiconductor devices may suffer from deteriorated electrical characteristics and low production yield. Accordingly, studies are being conducted to improve the electrical characteristics and production yield of the semiconductor devices.

### SUMMARY

An embodiment of the inventive concept provides a semiconductor device with improved electrical and reliability characteristics.

According to an embodiment of the inventive concept, a semiconductor device may include a substrate including a cell block region and a peripheral region, a memory cell array on the cell block region, and a peripheral capacitor structure on the peripheral region. The memory cell array may include an active pattern, a bit line structure on the active pattern, a cell capacitor structure electrically connected to the active pattern, and a cell conductive structure on the cell capacitor structure. The peripheral capacitor structure may include a first lower peripheral electrode placed at a level lower than the cell conductive structure, a second lower peripheral electrode spaced apart from the first lower peripheral electrode, a first upper peripheral electrode placed at a level higher than the first and second lower peripheral electrodes, and a second upper peripheral electrode spaced apart from the first upper peripheral electrode.

According to an embodiment of the inventive concept, a semiconductor device may include a substrate including a cell block region and a peripheral region, a memory cell array on the cell block region, and a peripheral capacitor structure on the peripheral region. The memory cell array may include an active pattern, a bit line structure on the active pattern, and a cell capacitor structure electrically connected to the active pattern. The peripheral capacitor structure may include a first lower peripheral electrode and a second lower peripheral electrode placed at a level lower than the cell capacitor structure, and a third lower peripheral electrode and a fourth lower peripheral electrode placed at a level higher than the bit line structure.

According to an embodiment of the inventive concept, a semiconductor device may include a substrate including a cell block region and a peripheral region, a memory cell array on the cell block region, and a peripheral capacitor structure on the peripheral region. The memory cell array may include an active pattern, a gate structure on the active pattern, a bit line contact on the active pattern, a bit line on the bit line contact, a bit line spacer in contact with a side surface of the bit line, a bit line capping layer in contact with a top surface of the bit line, a node contact on the active pattern, a landing pad on the node contact, a lower cell electrode on the landing pad, a cell supporter enclosing the lower cell electrode, an upper cell electrode spaced apart from the lower cell electrode and the cell supporter, and a cell capacitor insulating layer between the lower cell electrode and the upper cell electrode. The peripheral capacitor structure may include first and second lower peripheral electrodes placed at a level lower than the lower cell electrode, third and fourth lower peripheral electrodes placed at a level higher than the bit line capping layer, and first and second upper peripheral electrodes placed at a level higher than the upper cell electrode. The first and second lower peripheral electrodes may include the same material as the bit line, and the third and fourth lower peripheral electrodes may include the same material as the upper cell electrode.

### BRIEF DESCRIPTION OF THE DRAWINGS

FIG. 1 is a block diagram illustrating a memory system according to an embodiment of the inventive concept.

FIG. 2 is a block diagram illustrating a semiconductor device of FIG. 1.

FIG. 3 is a plan view illustrating a semiconductor device according to an embodiment of the inventive concept.

FIG. 4A is an enlarged plan view illustrating a portion Q1 of FIG. 3.

FIG. 4B is a sectional view taken along a line E1-E1′ of FIG. 4A.

FIG. 4C is a sectional view taken along a line E2-E2′ of FIG. 4A.

FIG. 4D is a sectional view taken along a line E3-E3′ of FIG. 4A.

FIG. 5A is an enlarged plan view illustrating a portion Q2 of FIG. 3.

FIG. 5B is a sectional view taken along a line E4-E4′ of FIG. 5A.

FIG. 5C is a sectional view taken along a line E5-E5′ of FIG. 5A.

FIG. 5D is a perspective view illustrating lower peripheral electrodes of a semiconductor device according to an embodiment of the inventive concept.

FIG. 6A is an enlarged plan view illustrating a portion Q3 of FIG. 3.

FIG. 6B is a sectional view taken along a line E6-E6′ of FIG. 6A.

FIG. 6C is a sectional view taken along a line E7-E7′ of FIG. 6A.

FIGS. 7A, 7B, 7C, 7D, 7E, 8A, 8B, 8C, 8D, 8E, 8F, and 8G are diagrams illustrating a method of fabricating a semiconductor device, according to an embodiment of the inventive concept.

FIGS. 9A and 9B are enlarged plan views illustrating peripheral electrodes of a semiconductor device according to an embodiment of the inventive concept.

FIG. 10A is an enlarged plan view illustrating a semiconductor device according to an embodiment of the inventive concept.

FIG. 10B is a sectional view taken along a line E8-E8′ of FIG. 10A.

FIG. 10C is a sectional view taken along a line E9-E9′ of FIG. 10A.

FIG. 10D is a sectional view taken along a line E10-E10′ of FIG. 10A.

FIG. 11 is a view illustrating a semiconductor device according to an embodiment of the inventive concept.

### DETAILED DESCRIPTION

Example embodiments of the inventive concepts will now be described more fully with reference to the accompanying drawings, in which example embodiments are shown. Like reference numerals in the drawings denote like elements, and thus their description may not be repeated.

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary. The term “consisting of,” on the other hand, indicates that a component is formed only of the element(s) listed.

Spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures.

As used herein, components described as being “electrically connected” are configured such that an electrical signal can be transferred from one component to the other (although such electrical signal may be attenuated in strength as it is transferred and may be selectively transferred).

Terms such as “same,” “equal,” “planar,” “coplanar,” “parallel,” and “perpendicular,” as used herein encompass identicality or near identicality including variations that may occur, for example, due to manufacturing processes.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

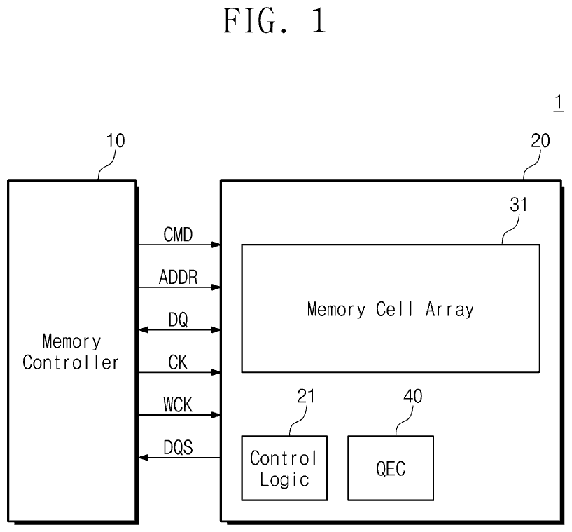

FIG. 1 is a block diagram illustrating a memory system according to an embodiment of the inventive concept.

Referring to FIG. 1, a memory system 1 may include a memory controller 10 and a semiconductor device 20.

The memory controller 10 may be configured to control an overall operation of the memory system 1 and control an overall data exchange between an external host and the semiconductor device 20. For example, the memory controller 10 may control the data-writing and data-reading operations on the semiconductor device 20, in respond to requests from the host.

In addition, the memory controller 10 may control the operation of the semiconductor device 20 by applying operation commands for controlling the semiconductor device 20. In an embodiment, the semiconductor device 20 may be a dynamic random-access memory (DRAM) device, a double data rate 4th generation synchronous DRAM (DDR4 SDRAM) device, a low power DDR4 (LPDDR4) SDRAM device, or an LPDDR5 SDRAM device with volatile memory cells.

The memory controller 10 may send a clock signal CK (or a command clock signal), a command CMD, and an address ADDR to the semiconductor device 20. When a data signal DQ is written in or read from the semiconductor device 20, the memory controller 10 may provide a data clock signal WCK to the semiconductor device 20. When the data signal DQ is transmitted to the memory controller 10, the semiconductor device 20 may provide a strobe signal DQS, along with the data signal DQ, to the memory controller 10.

The semiconductor device 20 may include a memory cell array 31, in which the data signal DQ is stored, a control logic circuit 21, and a quadrature error correction circuit (QEC) 40.

The control logic circuit 21 may control the operation of the semiconductor device 20. The QEC 40 may adjust a skew or a duty error of an input clock signal (with a 90° phase difference), which is generated based on the data clock signal WCK, to generate a correction clock signal with a phase difference of 90°.

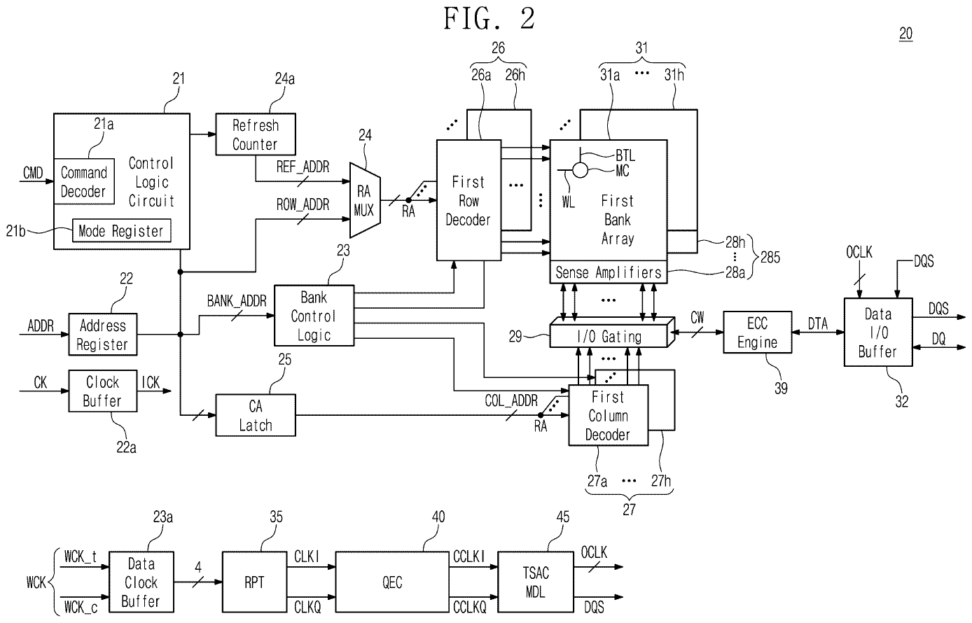

FIG. 2 is a block diagram illustrating a semiconductor device of FIG. 1.

Referring to FIG. 2, the semiconductor device 20 may include the control logic circuit 21, an address register 22, a bank control logic 23, a refresh counter 24a, a row address multiplexer 24, a column address latch 25, a row decoder 26, a column decoder 27, the memory cell array 31, a sense amplifier portion 28, an input/output gating circuit 29, an ECC engine 39, a clock buffer 22a, a data clock buffer 23a, a repeater 35, the QEC 40, and a tSAC matching delay circuit (TSAC MDL) 45.

The memory cell array 31 may include a plurality of bank arrays 31a to 31h. The semiconductor device 20 may include a plurality of row decoders 26 including row decoders 26a to 26h, which are electrically connected to the bank arrays 31a to 31h, respectively. The semiconductor device 20 may include a plurality of column decoders 27 including column decoders 27a to 27h, which are electrically connected to the bank arrays 31a to 31h, respectively. The sense amplifier portion 28 may include a plurality of sense amplifiers 28a to 28h, which are electrically connected to the bank arrays 31a to 31h, respectively.

The bank arrays 31a to 31h, the sense amplifiers 28a to 28h, the column decoders 27a to 27h, and the row decoders 26a to 26h may constitute first to eighth banks, respectively. Each of the first to eighth bank arrays 31a to 31h may include a plurality of word lines WL, a plurality of bit lines BTL, and a plurality of memory cells MC, which are formed at respective intersections of the word lines WL and the bit lines BTL, e.g., in a plan view.

The address register 22 may receive the address ADDR, which includes a bank address BANK_ADDR, a row address ROW_ADDR, and a column address COL_ADDR, from the memory controller 10. The address register 22 may provide the received bank address BANK_ADDR to the bank control logic 23, may provide the received row address ROW_ADDR to the row address multiplexer 24, and may provide the received column address COL_ADDR to the column address latch 25.

The bank control logic 23 may generate bank control signals in response to the bank address BANK_ADDR. One of the first to eighth row decoders 26a to 26h corresponding to the bank address BANK_ADDR may be activated in response to the bank control signals, and one of the column decoders 27a to 27h corresponding to the bank address BANK_ADDR may be activated.

The row address multiplexer 24 may receive the row address ROW_ADDR from the address register 22 and may receive a refresh row address REF_ADDR from the refresh counter 24a. The row address multiplexer 24 may selectively output the row address ROW_ADDR or the refresh row address REF_ADDR as a row address RA. The row address RA, which is output from the row address multiplexer 24, may be applied to each of the row decoders 26a to 26h.

The refresh counter 24a may be configured to sequentially increase or decrease the refresh row address REF_ADDR, under the control of the control logic circuit 21.

Among the row decoders 26a to 26h, the row decoder activated by the bank control logic 23 may decode the row address RA output from the row address multiplexer 24 to activate a word line corresponding to the row address RA. For example, the activated row decoder may apply a word line driving voltage to the word line corresponding to the row address RA.

The column address latch 25 may be configured to receive the column address COL_ADDR from the address register 22 and to temporarily store the received column address COL_ADDR. In addition, the column address latch 25 may gradually increase the received column address COL_ADDR, in a burst mode. The column address latch 25 may be configured to apply the column address COL_ADDR, which is temporarily stored or is gradually increased, to each of the column decoders 27a to 27h.

Among the column decoders 27a to 27h, the column decoder activated by the bank control logic 23 may activate the sense amplifier, which corresponds to the bank address BANK_ADDR and the column address COL_ADDR, through a corresponding input/output gating circuit 29.

The input/output gating circuit 29 may include an input data mask logic, readout data latches for storing data output from the bank arrays 31a to 31h, and writing drivers for writing data in the bank arrays 31a to 31h, in addition to circuits for gating input/output data.

A codeword CW, which will be read out from one of the bank arrays 31a to 31h, may be sensed by a sense amplifier corresponding to the bank array and may be stored in the readout data latch. The EBL engine 39 may perform an EBL decoding operation on the codeword CW, which is stored in the readout data latch, to generate data DTA and then may provide the data DTA to a data input/output buffer 32. The data input/output buffer 32 may convert the data DTA to the data signal DQ, based on an output clock signal OCLK, and then provide the data signal DQ, along with the strobe signal DQS, to the memory controller 10.

The data signal DQ, which will be written in one of the bank arrays 31a to 31h, may be converted to the data DTA by the data input/output buffer 32, and the data DTA may be provided to the EBL engine 39. Then, the EBL engine 39 may generate parity bits, based on the data DTA, and then, it may provide the codeword CW, which contains the data DTA and the parity bits to the input/output gating circuit 29. The input/output gating circuit 29 may write the codeword CW in a target page of the chosen one of the bank arrays using the writing drivers.

In a writing operation, the data input/output buffer 32 may convert the data signal DQ to the data DTA and then provide the data DTA to the EBL engine 39, and in a readout operation, the data input/output buffer 32 may convert the data DTA, which is provided from the EBL engine 39, to the data signal DQ based on the output clock signal OCLK and then provide the data signal DQ and the strobe signal DQS to the memory controller 10. For example, in the readout operation, the data input/output buffer 32 may output the data signal DQ to the outside, based on the output clock signal OCLK.

The clock buffer 22a may receive the clock signal CK and then perform a buffering operation on the clock signal CK to generate an inner clock signal ICK, which is provided to components that are used to process the command CMD and the address ADDR.

The data clock buffer 23a may be configured to receive a pair of differential clock signals WCK_t and WCK_c with opposite phases (e.g., 180°), to divide the pair of differential clock signals into clock signals with four different phases (e.g., with a 90°phase difference), and to output the clock signals with four different phases.

The repeater 35 may generate a pair of differential input signals from the clock signals with four different phases. The pair of differential input signals may include a first clock signal CLKI and a second clock signal CLKQ. The first clock signal CLKI and the second clock signal CLKQ may be provided to the QEC 40.

The QEC 40 may be configured to correct a skew between the first clock signal CLKI and the second clock signal CLKQ and to correct a duty error of the first and second clock signals CLKI and CLKQ. The QEC 40 may generate a pair of correction clock signals CCLKI and CCLKQ and may provide them to the TSAC MDL 45.

The TSAC MDL 45 may be configured to delay the pair of correction clock signals CCLKI and CCLKQ by a preset time tSAC, and then to output them. The preset time tSAC may be the time required for the pair of differential clock signals WCK_t and WCK_c, which are input to the data clock buffer 23a, to be output as data through the output buffer.

The TSAC MDL 45 may generate the output clock signal OCLK and the strobe signal DQS, based on the pair of correction clock signals CCLKI and CCLKQ. The TSAC MDL 45 may provide the output clock signal OCLK and the strobe signal DQS to the data input/output buffer 32.

The control logic circuit 21 may control the operation of the semiconductor device 20. For example, the control logic circuit 21 may generate control signals, which are used to execute a writing operation or a readout operation on the semiconductor device 20. The control logic circuit 21 may include a command decoder 21a, which is configured to decode the command CMD received from the memory controller 10, and a mode register 21b, which is configured to set an operation mode of the semiconductor device 20.

For example, the command decoder 21a may decode write enable signal, row address strobe signal, column address strobe signal, chip selection signal, and so forth, to generate the control signals corresponding to the command CMD.

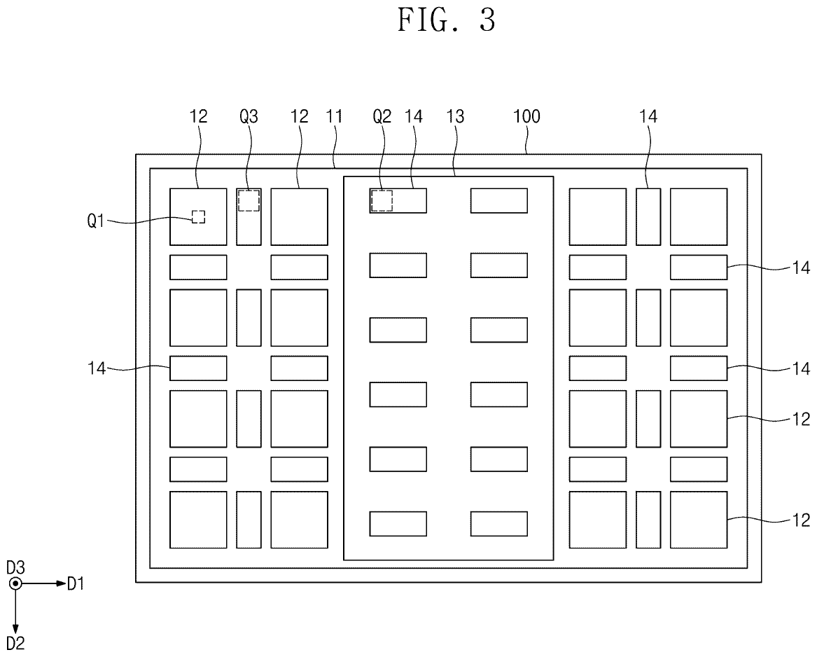

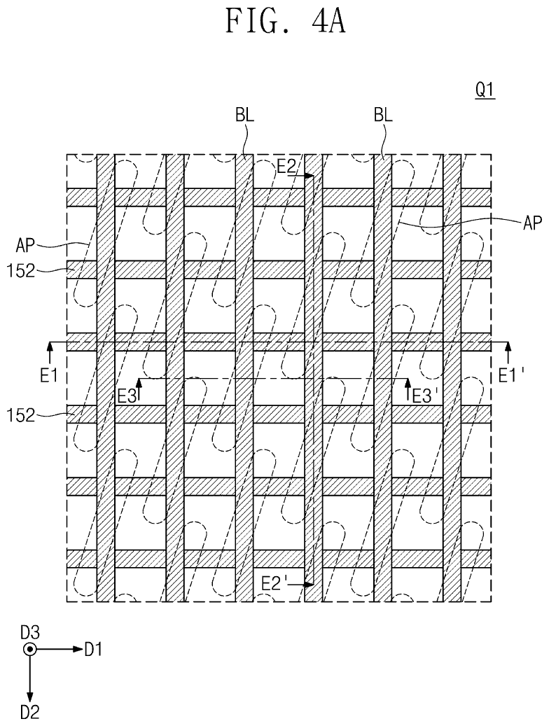

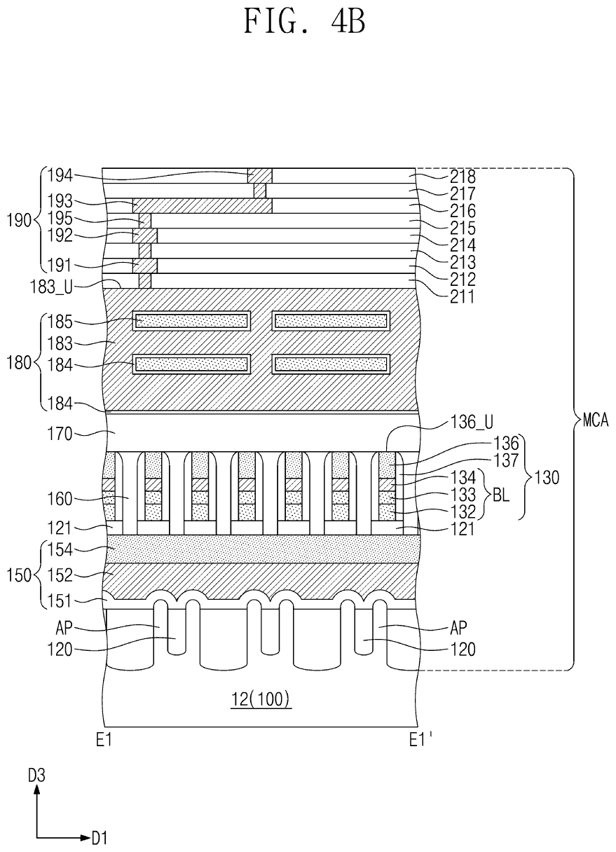

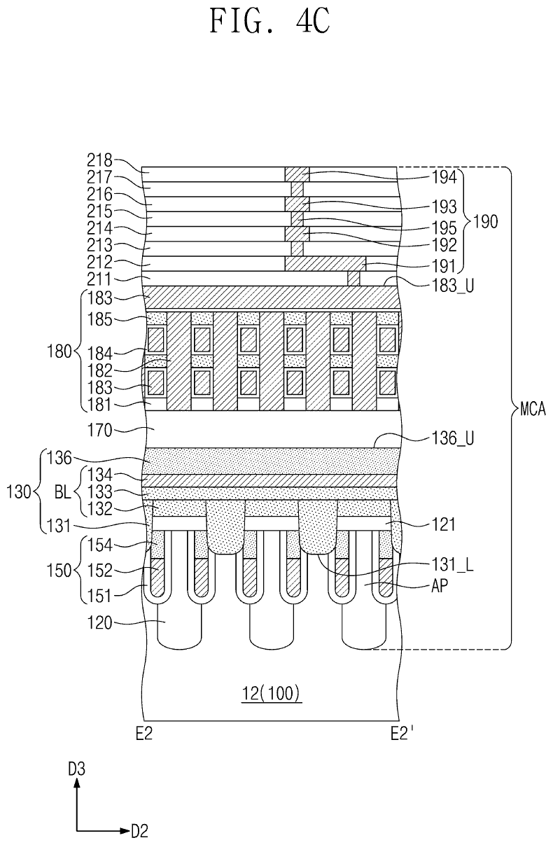

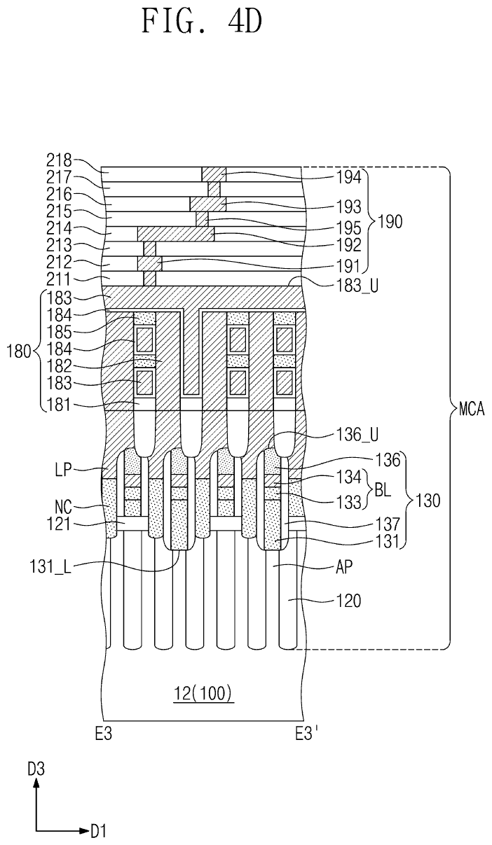

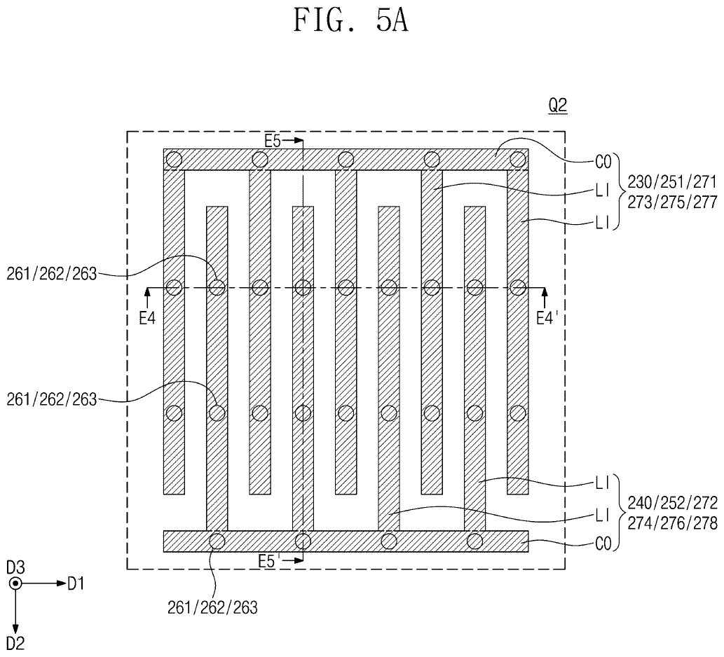

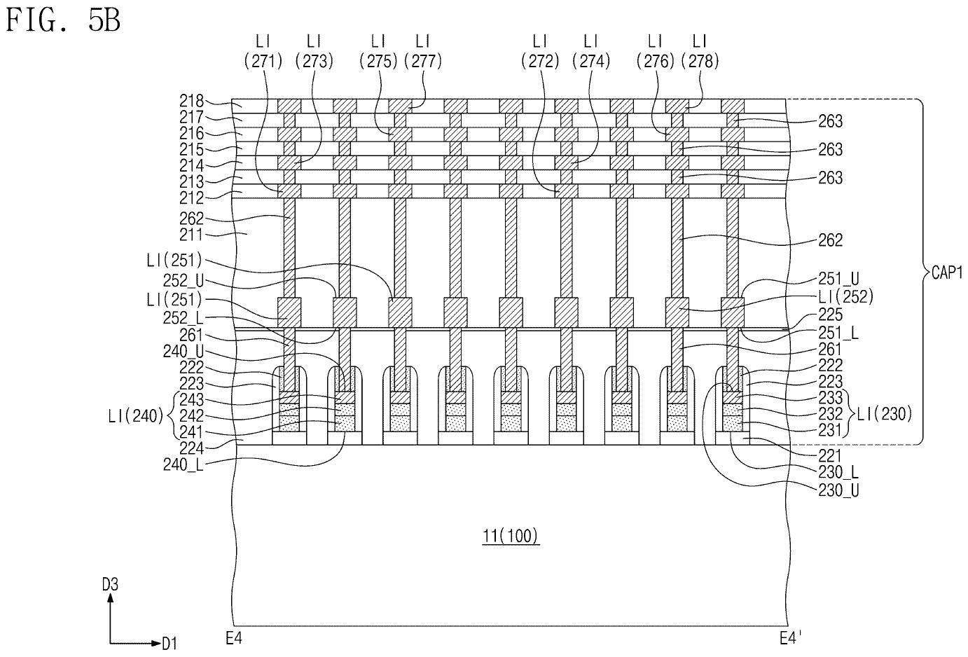

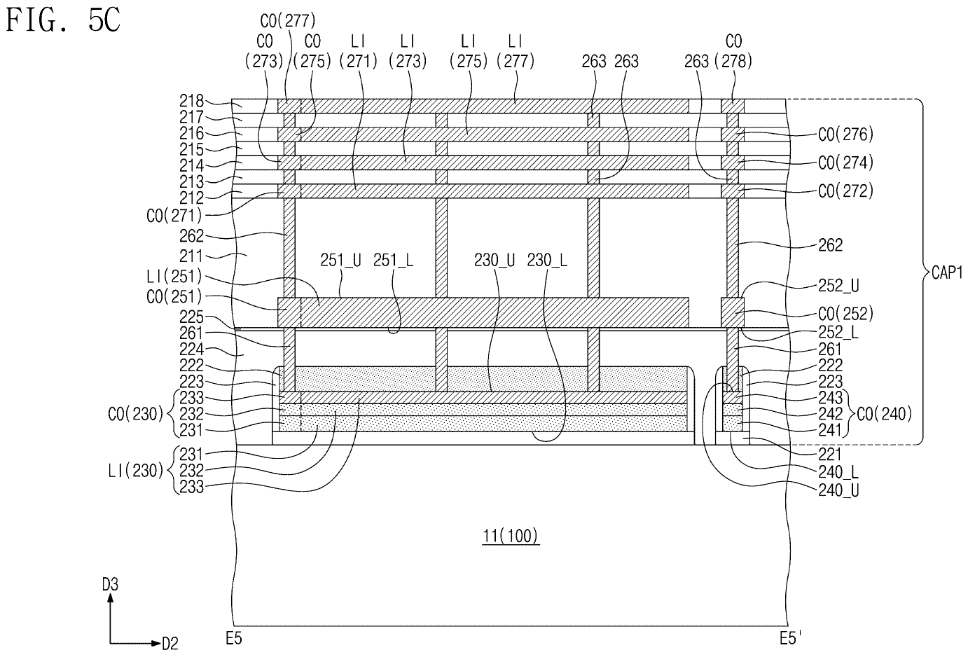

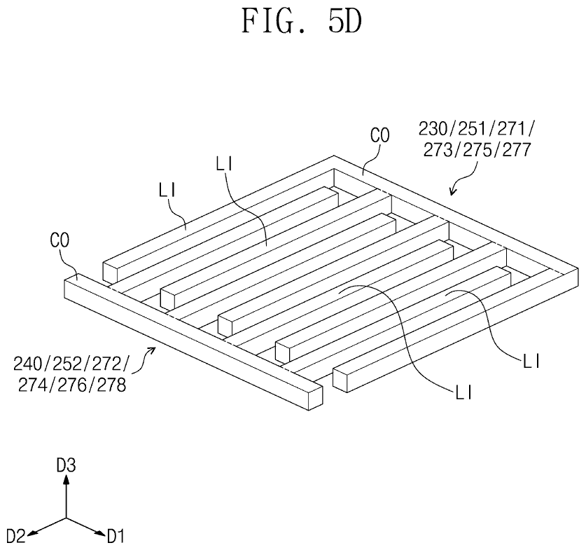

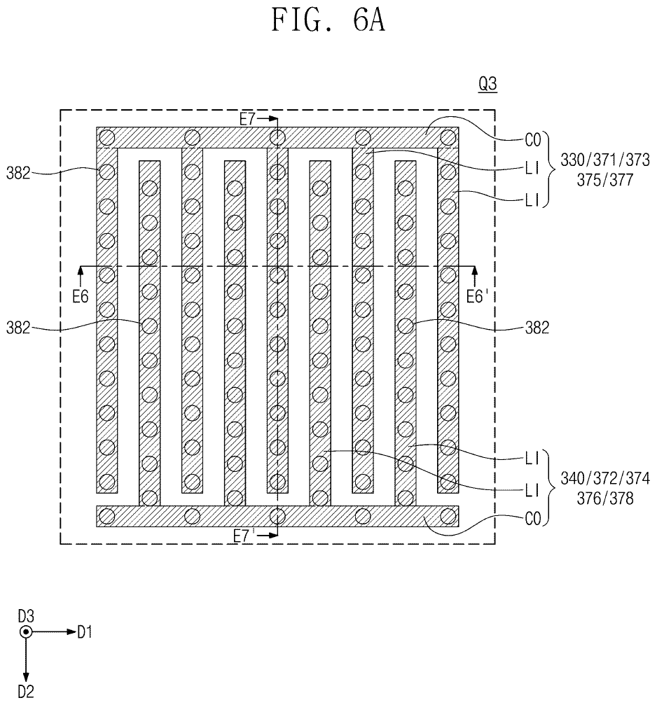

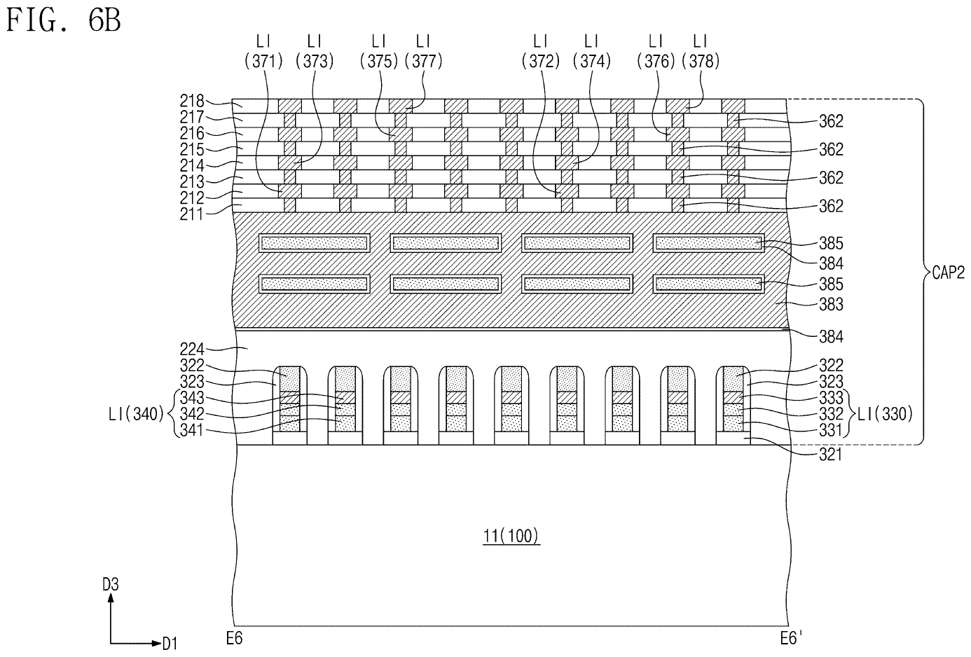

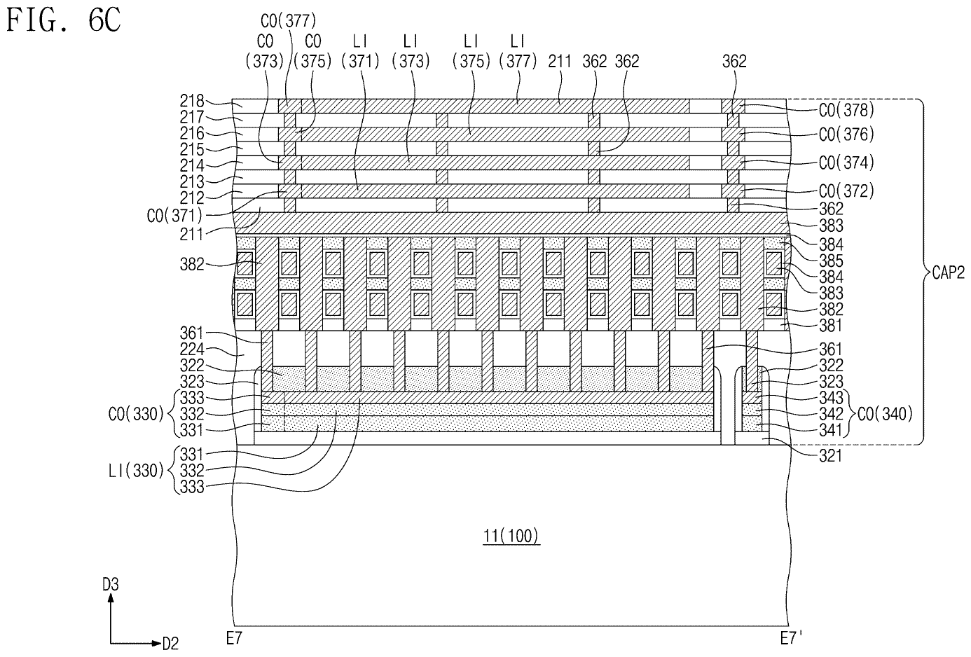

FIG. 3 is a plan view illustrating a semiconductor device according to an embodiment of the inventive concept. FIG. 4A is an enlarged plan view illustrating a portion Q1 of FIG. 3. FIG. 4B is a sectional view taken along a line E1-E1′ of FIG. 4A. FIG. 4C is a sectional view taken along a line E2-E2′ of FIG. 4A. FIG. 4D is a sectional view taken along a line E3-E3′ of FIG. 4A. FIG. 5A is an enlarged plan view illustrating a portion Q2 of FIG. 3. FIG. 5B is a sectional view taken along a line E4-E4′ of FIG. 5A. FIG. 5C is a sectional view taken along a line E5-E5′ of FIG. 5A. FIG. 5D is a perspective view illustrating lower peripheral electrodes of a semiconductor device according to an embodiment of the inventive concept. FIG. 6A is an enlarged plan view illustrating a portion Q3 of FIG. 3. FIG. 6B is a sectional view taken along a line E6-E6′ of FIG. 6A. FIG. 6C is a sectional view taken along a line E7-E7′ of FIG. 6A.

Referring to FIG. 3, the semiconductor device may include a substrate 100. In an embodiment, the substrate 100 may be a semiconductor substrate. As an example, semiconductor substrate may be formed of or include silicon, germanium, silicon-germanium, GaP, or GaAs. In an embodiment, the substrate 100 may be an insulating substrate or a semiconductor-on-insulator substrate. The substrate 100 may be a plate-shaped structure, which extends in a first direction D1 and a second direction D2. The first and second directions D1 and D2 may not be parallel to each other. As an example, the first and second directions D1 and D2 may be horizontal directions that are orthogonal to each other.

The substrate 100 may include cell block regions 12 and a peripheral region 11 enclosing the cell block regions 12, e.g., in a plan view. The cell block regions 12 and the peripheral region 11 may be two distinct regions, which are separated from each other in a plan view defined in the first and second directions D1 and D2. The peripheral region 11 may include a main peripheral region 13. The main peripheral region 13 may be disposed in a center region of the substrate 100. The cell block regions 12 may be respectively disposed at two opposite sides of the main peripheral region 13.

Circuit structures 14 may be disposed on the peripheral region 11. The circuit structures 14 may include the circuit structures 14 disposed on the main peripheral region 13 and the circuit structures 14 disposed between the cell block regions 12.

In an embodiment, a circuit structure 14 may include at least one of the control logic circuit 21, the command decoder 21a, the mode register 21b, the address register 22, the clock buffer 22a, the bank control logic 23, the data clock buffer 23a, the row address multiplexer 24, the refresh counter 24a, the column address latch 25, the row decoder 26, the column decoder 27, the sense amplifier portion 28, the input/output gating circuit 29, the data input/output buffer 32, the repeater 35, the EBL engine 39, the QEC 40, or the TSAC MDL 45 of FIG. 2.

In an embodiment, the circuit structure 14 may include a power capacitor structure. The power capacitor structure may be configured to store an electric power supplied to the semiconductor device.

In an embodiment, the circuit structure 14 may include an input/output circuit, a DC circuit, or an AC coupled pre-emphasis circuit.

Referring to FIGS. 4A, 4B, 4C, and 4D, the semiconductor device may include a memory cell array MCA on a cell block region 12.

The memory cell array MCA may include active patterns AP, a device isolation layer 120, gate structures 150, insulating patterns 121, bit line structures 130, node contacts NC, landing pads LP, insulating fences 160, a separation structure 170, a cell capacitor structure 180, and a cell conductive structure 190.

The active patterns AP may be or include upper portions of the cell block region 12 of the substrate 100 protruding in a third direction D3, e.g., from a bulk semiconductor layer of the substrate 100. The third direction D3 may not be parallel to the first and second directions D1 and D2. In an embodiment, the third direction D3 may be a vertical direction orthogonal to the first and second directions D1 and D2. The active patterns AP may be spaced apart from each other, e.g., in the first and second directions D1 and D2.

The device isolation layer 120 may be provided to define the active patterns AP. Each of the active patterns AP may be enclosed by the device isolation layer 120, e.g., in a plan view. The device isolation layer 120 may include an insulating material. As an example, the device isolation layer 120 may be formed of or include at least one of oxide or nitride materials.

Each of the gate structures 150 may be provided to extend lengthwise in the first direction D1. The gate structures 150 may be arranged to be spaced apart from each other in the second direction D2. The gate structures 150 may be provided on the device isolation layer 120 and the active patterns AP. A cell transistor may be defined by a gate structure 150 and an active pattern AP.

The gate structure 150 may include a gate insulating layer 151 on the active patterns AP, a gate conductive layer 152 on the gate insulating layer 151, and a gate capping layer 154 on the gate conductive layer 152.

The gate insulating layer 151 and the gate capping layer 154 may include an insulating material. As an example, the gate insulating layer 151 may include an oxide material, and the gate capping layer 154 may include a nitride material. The gate conductive layer 152 may include a conductive material.

The insulating patterns 121 may be provided on the gate structure 150 and the device isolation layer 120. The insulating patterns 121 may include an insulating material. In an embodiment, an insulating pattern 121 may include a plurality of insulating layers.

Each of the bit line structures 130 may be provided to extend lengthwise in the second direction D2. The bit line structures 130 may be arranged to be spaced apart from each other in the first direction D1. The bit line structures 130 may be provided on the cell block region 12 of the substrate 100. A bit line structure 130 may be provided on the insulating pattern 121 and the active pattern AP. The bit line structure 130 may be electrically connected to the active pattern AP.

Each of the bit line structures 130 may include a bit line BL, bit line contacts 131, a bit line capping layer 136, and a bit line spacer 137.

The bit line BL may be provided on the bit line contacts 131. The bit line BL may include first conductive layers 132, a second conductive layer 133 on the first conductive layers 132, and a third conductive layer 134 on the second conductive layer 133. The bit line capping layer 136 may be provided on the bit line BL. The bit line spacer 137 may be in contact with a side surface of the bit line BL. The bit line capping layer 136 may be in contact with a top surface of the bit line BL.

The bit line contacts 131 of the bit line structure 130 may be arranged to be spaced apart from each other in the second direction D2. The first conductive layers 132 of the bit line structure 130 may be arranged to be spaced apart from each other in the second direction D2. The bit line contacts 131 and the first conductive layers 132 of the bit line structure 130 may be alternately disposed in the second direction D2. The bit line contacts 131 may be disposed on the active patterns AP. The bit line contacts 131 may be provided to penetrate the insulating pattern 121. The first conductive layer 132 may be provided on the insulating pattern 121. The bit line contacts 131 and the first conductive layer 132 may include a conductive material. In an embodiment, the bit line contacts 131 and the first conductive layer 132 may be formed of or include poly silicon. In an embodiment, the bit line contacts 131 and the first conductive layers 132, which are included in each bit line structure 130, may be connected to each other to form a single object, in which any interface is not formed.

The second conductive layer 133 may be provided on the bit line contacts 131 and the first conductive layers 132. The third conductive layer 134 may be provided on the second conductive layer 133. The bit line capping layer 136 may be provided on the third conductive layer 134. Each of the second conductive layer 133 and the third conductive layer 134 may include a conductive material. As an example, the second conductive layer 133 may be formed of or include poly silicon, and the third conductive layer 134 may be formed of or include a metallic material. The bit line capping layer 136 may include an insulating material. In an embodiment, the number of the conductive layers, which are included in one bit line structure 130, may be greater or less than that in the illustrated example.

The bit line spacer 137 may cover a side surface of the bit line capping layer 136, side surfaces of the first to third conductive layers 132, 133, and 134, and side surfaces of the bit line contacts 131. The bit line spacer 137 may include an insulating material. In an embodiment, the bit line spacer 137 may include a plurality of insulating layers.

The node contacts NC may be provided. The node contacts NC may be provided on the active patterns AP. A node contact NC may be provided between adjacent bit line structures 130. The node contact NC may be provided on a side surface of the bit line structure 130. The node contacts NC may include a conductive material. As an example, the node contacts NC may be formed of or include poly silicon.

The landing pads LP may be provided. The landing pads LP may be provided on the node contacts NC. The landing pads LP may include a conductive material. In an embodiment, the landing pads LP may be formed of or include a metallic material. In an embodiment, a metal silicide layer may be provided between a node contact NC and a landing pad LP. In an embodiment, a barrier layer may be provided between the node contact NC and the landing pad LP.

The insulating fences 160 may be provided. The insulating fences 160 may be provided on the gate capping layer 154 of the gate structure 150. An insulating fence 160 may be provided between the node contacts NC, which are adjacent to each other in the second direction D2. The insulating fence 160 may be provided between the bit line structures 130, which are adjacent to each other in the first direction D1. The insulating fences 160 may include an insulating material.

The separation structure 170 may be provided on the insulating fence 160. The separation structure 170 may separate the landing pads LP from each other. The separation structure 170 may be provided to enclose the landing pad LP. For example, the separation structure 170 may contact and surround side surfaces of the landing pad LP. The separation structure 170 may include an insulating material.

The cell capacitor structure 180 may be provided on the landing pad LP and the separation structure 170. The cell capacitor structure 180 may be electrically connected to the active pattern AP through the landing pad LP and the node contact NC.

The cell capacitor structure 180 may include a cell etch stop layer 181, lower cell electrodes 182, an upper cell electrode 183, a cell capacitor insulating layer 184, and cell supporters 185.

The cell etch stop layer 181 may be provided on the separation structure 170. The cell etch stop layer 181 may include an insulating material.

A lower cell electrode 182 may have a circular pillar shape extending lengthwise in the third direction D3. The lower cell electrode 182 may be electrically connected to and/or contact the landing pad LP. The lower cell electrode 182 may be provided on the landing pad LP.

The cell capacitor insulating layer 184 may be provided on the lower cell electrodes 182 and the cell supporters 185. The cell capacitor insulating layer 184 may enclose/surround the lower cell electrodes 182 and the cell supporters 185. The cell capacitor insulating layer 184 may be provided between the lower cell electrodes 182 and the upper cell electrode 183.

The cell capacitor insulating layer 184 may include an insulating material. As an example, the cell capacitor insulating layer 184 may include an oxide material. In an embodiment, the cell capacitor insulating layer 184 may have a multi-layered structure including a plurality of insulating layers.

The upper cell electrode 183 may be provided on the cell capacitor insulating layer 184. The upper cell electrode 183 may enclose/surround the lower cell electrodes 182, the cell supporters 185, and the cell capacitor insulating layer 184. The upper cell electrode 183 may be spaced apart from the lower cell electrodes 182 and the cell supporters 185 with the cell capacitor insulating layer 184 interposed therebetween.

The cell supporters 185 may support the lower cell electrodes 182. The cell supporters 185 may enclose/surround the lower cell electrodes 182. The cell supporters 185 may include an insulating material. As an example, the cell supporters 185 may be formed of or include silicon carbon nitride.

The lower cell electrodes 182 may include a conductive material. In an embodiment, the lower cell electrodes 182 may be formed of or include TiSiN. The upper cell electrode 183 may include a conductive material. As an example, the upper cell electrode 183 may be formed of or include TiN.

A first upper insulating layer 211 may be provided on the upper cell electrode 183 of the cell capacitor structure 180. A second upper insulating layer 212 may be provided on the first upper insulating layer 211. A third upper insulating layer 213 may be provided on the second upper insulating layer 212. A fourth upper insulating layer 214 may be provided on the third upper insulating layer 213. A fifth upper insulating layer 215 may be provided on the fourth upper insulating layer 214. A sixth upper insulating layer 216 may be provided on the fifth upper insulating layer 215. A seventh upper insulating layer 217 may be provided on the sixth upper insulating layer 216. An eighth upper insulating layer 218 may be provided on the seventh upper insulating layer 217. The first to eighth upper insulating layers 211 to 218 may include an insulating material. In an embodiment, the first to eighth upper insulating layers 211 to 218 may include an oxide material. In an embodiment, each of the first to eighth upper insulating layers 211 to 218 may have a multi-layered structure including a plurality of insulating layers.

The cell conductive structure 190 may be provided on the cell capacitor structure 180. The cell conductive structure 190 may include first conductive lines 191 in the second upper insulating layer 212, second conductive lines 192 in the fourth upper insulating layer 214, third conductive lines 193 in the sixth upper insulating layer 216, fourth conductive lines 194 in the eighth upper insulating layer 218, and first vias 195.

The first vias 195 may be provided in the first, third, fifth, or seventh upper insulating layer 211, 213, 215, or 217. The first vias 195 may be disposed between the upper cell electrode 183 and the first conductive line 191, between the first and second conductive lines 191 and 192, between the second and third conductive lines 192 and 193, or between the third and fourth conductive lines 193 and 194. The first to fourth conductive lines 191, 192, 193, and 194 and the upper cell electrode 183 may be electrically connected to each other through the first vias 195.

The first to fourth conductive lines 191, 192, 193, and 194 and the first vias 195 may include a conductive material.

Referring to FIGS. 5A, 5B, 5C, and 5D, at least one of the circuit structures 14 may include a peripheral capacitor structure CAP1. The peripheral capacitor structure CAP1 may be provided on the peripheral region 11. The peripheral capacitor structure CAP1 may be included in a circuit structure 14, which is disposed on the main peripheral region 13 or between the cell block regions 12.

The peripheral capacitor structure CAP1 may be, for example, a capacitor included in the input/output circuit of the circuit structure 14. The input/output circuit may be, for example, the data clock buffer 23a or the data input/output buffer 32 of FIG. 2. The peripheral capacitor structure CAP1 may be, for example, a capacitor included in the DC circuit of the circuit structure 14. The DC circuit may be configured to convert an external voltage to an internal voltage. In an embodiment, the DC circuit may be included in at least one of the command decoder 21a, the address register 22, the clock buffer 22a, the column address latch 25, or the data input/output buffer 32 of FIG. 2. The peripheral capacitor structure CAP1 may be, for example, a capacitor included in the AC coupled pre-emphasis circuit.

The peripheral capacitor structure CAP1 may include a first lower peripheral electrode 230, a second lower peripheral electrode 240, a third lower peripheral electrode 251, a fourth lower peripheral electrode 252, a first upper peripheral electrode 271, a second upper peripheral electrode 272, a third upper peripheral electrode 273, a fourth upper peripheral electrode 274, a fifth upper peripheral electrode 275, a sixth upper peripheral electrode 276, a seventh upper peripheral electrode 277, an eighth upper peripheral electrode 278, peripheral insulating patterns 221, peripheral capping layers 222, and peripheral spacers 223.

The peripheral insulating patterns 221 may be provided on the peripheral region 11 of the substrate 100. The peripheral insulating patterns 221 may include the same insulating material as the insulating patterns 121.

The first and second lower peripheral electrodes 230 and 240 may be provided on the peripheral insulating patterns 221. The first and second lower peripheral electrodes 230 and 240 may be placed at a level lower than the cell capacitor structure 180 and the cell conductive structure 190. The first and second lower peripheral electrodes 230 and 240 may be placed at a level lower than the lower cell electrode 182. The first and second lower peripheral electrodes 230 and 240 may be spaced apart from each other, e.g., with a lower insulating layer 224 interposed therebetween. The first and second lower peripheral electrodes 230 and 240 may be electrically disconnected (e.g., electrically insulated) from each other.

The first and second lower peripheral electrodes 230 and 240 may be placed at the same level. The first and second lower peripheral electrodes 230 and 240 may be placed at the same level as the bit line structure 130. The first and second lower peripheral electrodes 230 and 240 may be placed at the same level as the bit line BL. The first and second lower peripheral electrodes 230 and 240 may be placed at a level lower than the uppermost portion 136_U of the bit line capping layer 136. The first and second lower peripheral electrodes 230 and 240 may be placed at a level higher than the lowermost portion 131_L of a bit line contact 131. The first and second lower peripheral electrodes 230 and 240 may include the same material as the bit line BL.

Top surfaces 230_U and 240_U of the first and second lower peripheral electrodes 230 and 240 may be placed at a level lower than the uppermost portion 136_U of the bit line capping layer 136. Bottom surfaces 230_L and 240_L of the first and second lower peripheral electrodes 230 and 240 may be placed at a level higher than the lowermost portion 131_L of the bit line contact 131. The top surfaces 230_U and 240_U of the first and second lower peripheral electrodes 230 and 240 may be placed at the same level as the top surface of the bit line BL. The bottom surfaces 230_L and 240_L of the first and second lower peripheral electrodes 230 and 240 may be placed at the same level as a bottom surface of the bit line BL.

The peripheral capping layer 222 may be in contact with the top surface 230_U of the first lower peripheral electrode 230 or the top surface 240_U of the second lower peripheral electrode 240. The peripheral capping layer 222 may include the same insulating material as the bit line capping layer 136.

The peripheral spacer 223 may be in contact with a side surface of the first lower peripheral electrode 230 or a side surface of the second lower peripheral electrode 240. The peripheral spacer 223 may also be in contact with a side surface of the peripheral capping layer 222. The peripheral spacer 223 may include the same insulating material as the bit line spacer 137.

The first lower peripheral electrode 230 may include a first electrode layer 231, a second electrode layer 232 on the first electrode layer 231, and a third electrode layer 233 on the second electrode layer 232. The second lower peripheral electrode 240 may include a first electrode layer 241, a second electrode layer 242 on the first electrode layer 241, and a third electrode layer 243 on the second electrode layer 242. The first electrode layers 231 and 241 may include the same conductive material as the first conductive layer 132. As an example, the first electrode layers 231 and 241 and the first conductive layer 132 may be formed of or include poly silicon. The second electrode layers 232 and 242 may include the same conductive material as the second conductive layer 133. As an example, the second electrode layers 232 and 242 and the second conductive layer 133 may be formed of or include poly silicon. The third electrode layers 233 and 243 may include the same conductive material as the third conductive layer 134. As an example, the third electrode layers 233 and 243 and the third conductive layer 134 may be formed of or include a metallic material.

A lower insulating layer 224 may be provided to cover the first and second lower peripheral electrodes 230 and 240. The first and second lower peripheral electrodes 230 and 240 may be provided in the lower insulating layer 224. The lower insulating layer 224 may include portions that are interposed between the first and second lower peripheral electrodes 230 and 240, e.g., in the first direction D1. The portions of the lower insulating layer 224, which are interposed between the first and second lower peripheral electrodes 230 and 240, may serve as a capacitor insulating layer of the peripheral capacitor structure CAP1. The lower insulating layer 224 may include an insulating material. In an embodiment, the lower insulating layer 224 may have a multi-layered structure including a plurality of insulating layers.

An interlayer insulating layer 225 may be provided on the lower insulating layer 224. The interlayer insulating layer 225 may include the same insulating material as the cell capacitor insulating layer 184.

The third lower peripheral electrode 251 and the fourth lower peripheral electrode 252 may be provided on the interlayer insulating layer 225. The third and fourth lower peripheral electrodes 251 and 252 may be placed at a level lower than the cell conductive structure 190. The third and fourth lower peripheral electrodes 251 and 252 may be spaced apart from each other. The third and fourth lower peripheral electrodes 251 and 252 may be electrically disconnected (e.g., electrically insulated) from each other. The third and fourth lower peripheral electrodes 251 and 252 may be placed at a level higher than the first and second lower peripheral electrodes 230 and 240. The third and fourth lower peripheral electrodes 251 and 252 may be placed at a level higher than the bit line structure 130. The third and fourth lower peripheral electrodes 251 and 252 may be placed at the same level. The third and fourth lower peripheral electrodes 251 and 252 may be disposed between the first and second lower peripheral electrodes 230 and 240 and the first and second upper peripheral electrodes 271 and 272.

The third and fourth lower peripheral electrodes 251 and 252 may be placed at a level higher than the uppermost portion 136_U of the bit line capping layer 136. The third and fourth lower peripheral electrodes 251 and 252 may be placed at a level lower than the uppermost portion 183_U of the upper cell electrode 183. The third and fourth lower peripheral electrodes 251 and 252 may include the same conductive material as the upper cell electrode 183. In an embodiment, the third and fourth lower peripheral electrodes 251 and 252 and the upper cell electrode 183 may be formed of or include TiN.

Top surfaces 251_U and 252_U of the third and fourth lower peripheral electrodes 251 and 252 may be placed at a level lower than the uppermost portion 183_U of the upper cell electrode 183. Bottom surfaces 251_L and 252_L of the third and fourth lower peripheral electrodes 251 and 252 may be placed at a level higher than the uppermost portion 136_U of the bit line capping layer 136.

The first upper insulating layer 211 may cover the third and fourth lower peripheral electrodes 251 and 252. The third and fourth lower peripheral electrodes 251 and 252 may be provided in the first upper insulating layer 211. The first upper insulating layer 211 may include portions interposed between the third and fourth lower peripheral electrodes 251 and 252. The portions of the first upper insulating layer 211, which are interposed between the third and fourth lower peripheral electrodes 251 and 252, may serve as a capacitor insulating layer of the peripheral capacitor structure CAP1.

The first to eighth upper peripheral electrodes 271 to 278 may be placed at a level higher than the first to fourth lower peripheral electrodes 230, 240, 251, and 252. The first to eighth upper peripheral electrodes 271 to 278 may be placed at a level higher than the upper cell electrode 183 of the cell capacitor structure 180.

The first and second upper peripheral electrodes 271 and 272 may be provided in the second upper insulating layer 212. The first and second upper peripheral electrodes 271 and 272 may be spaced apart from each other. The first and second upper peripheral electrodes 271 and 272 may be electrically disconnected (e.g., electrically insulated) from each other. The second upper insulating layer 212 may include portions interposed between the first and second upper peripheral electrodes 271 and 272. The first and second upper peripheral electrodes 271 and 272 may be placed at the same level as the first conductive line 191. The first and second upper peripheral electrodes 271 and 272 may include the same conductive material as the first conductive line 191.

The third and fourth upper peripheral electrodes 273 and 274 may be provided in the fourth upper insulating layer 214. The third and fourth upper peripheral electrodes 273 and 274 may be spaced apart from each other. The third and fourth upper peripheral electrodes 273 and 274 may be electrically disconnected (e.g., electrically insulated) from each other. The fourth upper insulating layer 214 may include portions interposed between the third and fourth upper peripheral electrodes 273 and 274. The third and fourth upper peripheral electrodes 273 and 274 may be placed at the same level as the second conductive line 192. The third and fourth upper peripheral electrodes 273 and 274 may be placed at a level higher than the first and second upper peripheral electrodes 271 and 272. The third and fourth upper peripheral electrodes 273 and 274 may include the same conductive material as the second conductive line 192.

The fifth and sixth upper peripheral electrodes 275 and 276 may be provided in the sixth upper insulating layer 216. The fifth and sixth upper peripheral electrodes 275 and 276 may be spaced apart from each other. The fifth and sixth upper peripheral electrodes 275 and 276 may be electrically disconnected (e.g., electrically insulated) from each other. The sixth upper insulating layer 216 may include portions interposed between the fifth and sixth upper peripheral electrodes 275 and 276. The fifth and sixth upper peripheral electrodes 275 and 276 may be placed at the same level as the third conductive line 193. The fifth and sixth upper peripheral electrodes 275 and 276 may include the same conductive material as the third conductive line 193.

The seventh and eighth upper peripheral electrodes 277 and 278 may be provided in the eighth upper insulating layer 218. The seventh and eighth upper peripheral electrodes 277 and 278 may be spaced apart from each other. The seventh and eighth upper peripheral electrodes 277 and 278 may be electrically disconnected (e.g., electrically insulated) from each other. The eighth upper insulating layer 218 may include portions interposed between the seventh and eighth upper peripheral electrodes 277 and 278. The seventh and eighth upper peripheral electrodes 277 and 278 may be placed at the same level as the fourth conductive line 194. The seventh and eighth upper peripheral electrodes 277 and 278 may include the same conductive material as the fourth conductive line 194.

The number of the upper peripheral electrodes 271 to 278 is not limited to that in the illustrated embodiment. In some embodiments, the number of the upper peripheral electrodes 271 to 278 may be less than or equal to six and may be greater than or equal to ten.

Each of the first to fourth lower peripheral electrodes 230, 240, 251, and 252 and the first to eighth upper peripheral electrodes 271 to 278 may include line portions LI and a connecting portion CO electrically connecting the line portions LI.

Each of the line portions LI may extend lengthwise in the second direction D2. The connecting portion CO may extend lengthwise in the first direction D1. The line portions LI of the first lower peripheral electrode 230 may be arranged to be spaced apart from each other in the first direction D1. The line portions LI of the second lower peripheral electrode 240 may be arranged to be spaced apart from each other in the first direction D1. The first and second lower peripheral electrodes 230 and 240 may be provided in such a way that the line portions LI thereof are alternately arranged to be spaced apart from each other in the first direction D1. The line portions LI of the third lower peripheral electrode 251 may be arranged to be spaced apart from each other in the first direction D1. The line portions LI of the fourth lower peripheral electrode 252 may be arranged to be spaced apart from each other in the first direction D1. The third and fourth lower peripheral electrodes 251 and 252 may be provided in such a way that the line portions LI thereof are alternately arranged to be spaced apart from each other in the first direction D1.

The line portions LI of the first and second lower peripheral electrodes 230 and 240 may be disposed between the connecting portions CO of the first and second lower peripheral electrodes 230 and 240. The line portions LI of the third and fourth lower peripheral electrodes 251 and 252 may be disposed between the connecting portions CO of the third and fourth lower peripheral electrodes 251 and 252.

The first and third lower peripheral electrodes 230 and 251 and the first, third, fifth and seventh upper peripheral electrodes 271, 273, 275, and 277 may overlap each other in the third direction D3. The line portions LI of the first and third lower peripheral electrodes 230 and 251 and the first, third, fifth and seventh upper peripheral electrodes 271, 273, 275, and 277 may overlap each other in the third direction D3. The connecting portions CO of the first and third lower peripheral electrodes 230 and 251 and the first, third, fifth and seventh upper peripheral electrodes 271, 273, 275, and 277 may overlap each other in the third direction D3.

The second and fourth lower peripheral electrodes 240 and 252 and the second, fourth, sixth and eighth upper peripheral electrodes 272, 274, 276, and 278 may overlap each other in the third direction D3. The line portions LI of the second and fourth lower peripheral electrodes 240 and 252 and the second, fourth, sixth and eighth upper peripheral electrodes 272, 274, 276, and 278 may overlap each other in the third direction D3. The connecting portions CO of the second and fourth lower peripheral electrodes 240 and 252 and the second, fourth, sixth and eighth upper peripheral electrodes 272, 274, 276, and 278 may overlap each other in the third direction D3.

The first and third lower peripheral electrodes 230 and 251 and the first, third, fifth and seventh upper peripheral electrodes 271, 273, 275, and 277 may be electrically connected to each other. The second and fourth lower peripheral electrodes 240 and 252 and the second, fourth, sixth and eighth upper peripheral electrodes 272, 274, 276, and 278 may be electrically connected to each other.

Second vias 261, which are enclosed by the interlayer insulating layer 225 and the lower insulating layer 224, may be provided. The second vias 261 may be provided to electrically connect the first and third lower peripheral electrodes 230 and 251 to each other or to electrically connect the second and fourth lower peripheral electrodes 240 and 252 to each other. The second vias 261 may include a conductive material.

Third vias 262, which are enclosed by the first upper insulating layer 211, may be provided. The third vias 262 may be provided to electrically connect the third lower peripheral electrode 251 to the first upper peripheral electrode 271 or to electrically connect the fourth lower peripheral electrode 252 to the second upper peripheral electrode 272. The third vias 262 may include a conductive material.

Fourth vias 263 may be provided. The fourth vias 263 may be enclosed by the third, fifth, or seventh upper insulating layer 213, 215, or 217. The fourth vias 263 may be provided to electrically connect the first, third, fifth and seventh upper peripheral electrodes 271, 273, 275, and 277 to each other and to electrically connect the second, fourth, sixth and eighth upper peripheral electrodes 272, 274, 276, and 278 to each other.

Referring to FIGS. 6A, 6B, and 6C, at least one of the circuit structures 14 may include a power capacitor structure CAP2. The power capacitor structure CAP2 may be provided on the peripheral region 11. The power capacitor structure CAP2 may be included in the circuit structure 14, which is disposed on the main peripheral region 13 or between the cell block regions 12.

The power capacitor structure CAP2 may include a first lower power electrode 330, a second lower power electrode 340, a first upper power electrode 371, a second upper power electrode 372, a third upper power electrode 373, a fourth upper power electrode 374, a fifth upper power electrode 375, a sixth upper power electrode 376, a seventh upper power electrode 377, an eighth upper power electrode 378, power insulating patterns 321, power capping layers 322, power spacers 323, a power etch stop layer 381, third lower power electrodes 382, a fourth lower power electrode 383, a power capacitor insulating layer 384, and power supporters 385.

The power insulating patterns 321 may be provided on the peripheral region 11 of the substrate 100. The power insulating patterns 321 may include the same insulating material as the insulating patterns 121 and the peripheral insulating patterns 221.

The first and second lower power electrodes 330 and 340 may be placed at a level lower than the cell capacitor structure 180 and the cell conductive structure 190. The first and second lower power electrodes 330 and 340 may be electrically connected to each other. As an example, the first and second lower power electrodes 330 and 340 may be electrically connected to each other through a conductive line, which is commonly connected to and/or contact the first and second lower power electrodes 330 and 340. The first and second lower power electrodes 330 and 340 may have a structure the same as or similar to a structure of the first and second lower peripheral electrodes 230 and 240.

The power capping layer 322 may include the same insulating material as the bit line capping layer 136 and the peripheral capping layer 222. The power spacer 323 may include the same insulating material as the bit line spacer 137 and the peripheral spacer 223.

The first lower power electrode 330 may include a first power layer 331, a second power layer 332, and a third power layer 333. The second lower power electrode 340 may include a first power layer 341, a second power layer 342, and a third power layer 343. The first power layers 331 and 341 may include the same conductive material as the first electrode layers 231 and 241 and the first conductive layer 132. The second power layers 332 and 342 may include the same conductive material as the second electrode layers 232 and 242 and the second conductive layer 133. The third power layers 333 and 343 may include the same conductive material as the third electrode layers 233 and 243 and the third conductive layer 134.

The lower insulating layer 224 may cover the first and second lower power electrodes 330 and 340. The first and second lower power electrodes 330 and 340 may be provided in the lower insulating layer 224.

The power etch stop layer 381 may be provided on a lower insulating layer 244. The power etch stop layer 381 may include the same insulating material as the cell etch stop layer 181. The power etch stop layer 381 may have a structure the same as or similar to a structure of the cell etch stop layer 181.

The third lower power electrode 382 may have a structure the same as or similar to a structure of the lower cell electrode 182. The third lower power electrode 382 may have a circular pillar shape extending lengthwise in the third direction D3. A length of the third lower power electrode 382 in the third direction D3 may be equal to a length of the lower cell electrode 182 in the third direction D3. The third lower power electrode 382 may include the same conductive material as the lower cell electrode 182.

The power capacitor insulating layer 384 may be provided on the third lower power electrode 382 and the power supporters 385. The power capacitor insulating layer 384 may enclose the third lower power electrodes 382 and the power supporters 385. The power capacitor insulating layer 384 may be provided between the third lower power electrodes 382 and the fourth lower power electrode 383. The power capacitor insulating layer 384 may include the same insulating material as the cell capacitor insulating layer 184.

The fourth lower power electrode 383 may be provided on the power capacitor insulating layer 384. The fourth lower power electrode 383 may enclose the third lower power electrodes 382, the power supporters 385, and the power capacitor insulating layer 384. The fourth lower power electrode 383 may be spaced apart from the third lower power electrodes 382 and the power supporters 385, e.g., with the power capacitor insulating layer 384 interposed therebetween. The fourth lower power electrode 383 may include the same conductive material as the upper cell electrode 183.

The power supporters 385 may support the third lower power electrodes 382. The power supporters 385 may enclose the third lower power electrodes 382. The power supporters 385 may include the same insulating material as the cell supporters 185.

The first upper insulating layer 211 may be provided on the fourth lower power electrode 383. The third and fourth lower power electrodes 382 and 383 may be placed at a level that is higher than the bit line structure 130 and is lower than the cell conductive structure 190. The third and fourth lower power electrodes 382 and 383 may be placed at the same level as the cell capacitor structure 180.

The first and second upper power electrodes 371 and 372 may be placed at the same level as the first and second upper peripheral electrodes 271 and 272 and the first conductive line 191. The first and second upper power electrodes 371 and 372 may include the same conductive material as the first and second upper peripheral electrodes 271 and 272 and the first conductive line 191.

The third and fourth upper power electrodes 373 and 374 may be placed at the same level as the third and fourth upper peripheral electrodes 273 and 274 and the second conductive line 192. The third and fourth upper power electrodes 373 and 374 may include the same conductive material as the third and fourth upper peripheral electrodes 273 and 274 and the second conductive line 192.

The fifth and sixth upper power electrodes 375 and 376 may be placed at the same level as the fifth and sixth upper peripheral electrodes 275 and 276 and the third conductive line 193. The fifth and sixth upper power electrodes 375 and 376 may include the same conductive material as the fifth and sixth upper peripheral electrodes 275 and 276 and the third conductive line 193.

The seventh and eighth upper power electrodes 377 and 378 may be placed at the same level as the seventh and eighth upper peripheral electrodes 277 and 278 and the fourth conductive line 194. The seventh and eighth upper power electrodes 377 and 378 may include the same conductive material as the seventh and eighth upper peripheral electrodes 277 and 278 and the fourth conductive line 194.

First to eighth upper power electrodes 371 to 378 may have a structure the same as or similar to a structure of the first to eighth upper peripheral electrodes 271 to 278. The number of the upper power electrodes 371 to 378 is not limited to that in the illustrated embodiment. The first to eighth upper power electrodes 371 to 378 may be placed at a level higher than the cell capacitor structure 180 and the first to fourth lower power electrodes 330, 340, 382, and 383.

Each of the first and second lower power electrodes 330 and 340 and the first to eighth upper power electrodes 371 to 378 may include the line portions LI and the connecting portion CO electrically connecting the line portions LI.

The first to third lower power electrodes 330, 340, and 382 may be electrically connected to each other. The fourth lower power electrode 383 and the first to eighth upper power electrodes 371 to 378 may be electrically connected to each other.

Fifth vias 361 may be provided and may be enclosed by the lower insulating layer 224. The fifth vias 361 may be provided to electrically connect the first and third lower power electrodes 330 and 382 to each other or to electrically connect the second and third lower power electrodes 340 and 382 to each other. The fifth vias 361 may include a conductive material.

Sixth vias 362 may be provided. The sixth vias 362 may be enclosed by the first, third, fifth, or seventh upper insulating layer 211, 213, 215, or 217. The sixth vias 362 may be provided to electrically connect the first, third, fifth and seventh upper power electrodes 371, 373, 375, and 377 to the fourth lower power electrode 383.

In the semiconductor device according to an embodiment of the inventive concept, since the peripheral capacitor structure CAP1 includes the first to fourth lower peripheral electrodes 230, 240, 251, and 252 and the power capacitor structure CAP2 includes the first and second lower power electrodes 330 and 340, the capacitance of the peripheral and power capacitor structures CAP1 and CAP2 may be increased.

In the semiconductor device according to an embodiment of the inventive concept, since the first to fourth lower peripheral electrodes 230, 240, 251, and 252 of the peripheral capacitor structure CAP1 includes a metallic material and the first and second lower power electrodes 330 and 340 of the power capacitor structure CAP2 includes a metallic material, the peripheral and power capacitor structures CAP1 and CAP2 may have improved frequency and voltage stability compared to a MOS capacitor.

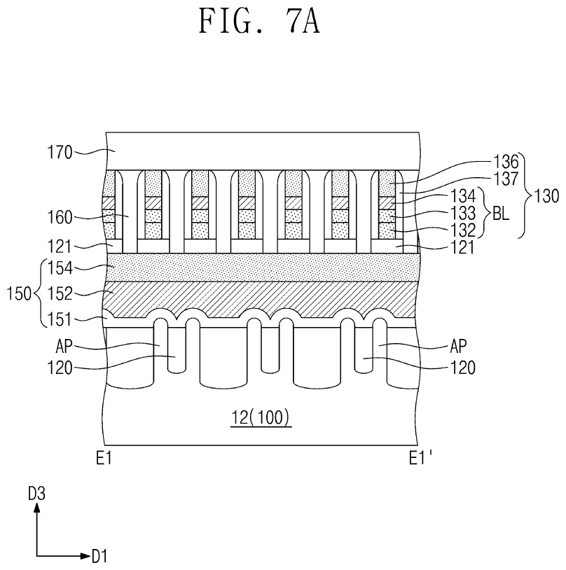

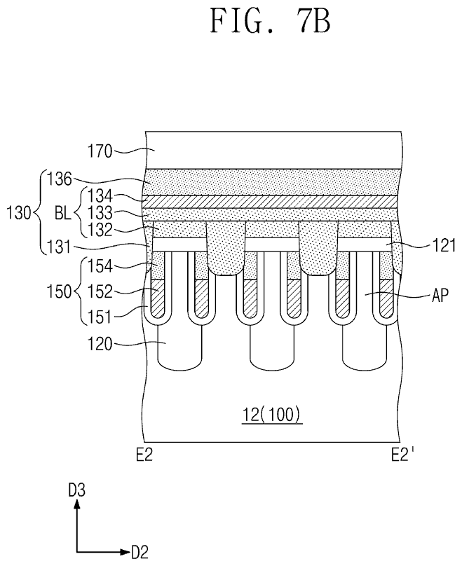

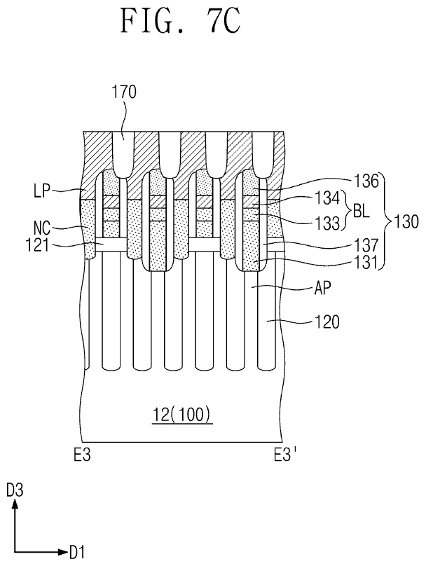

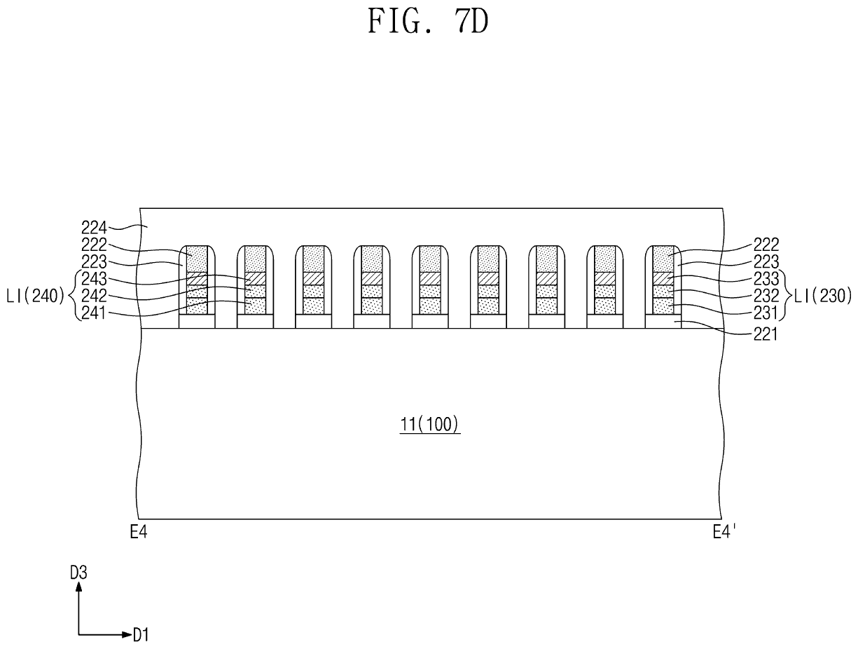

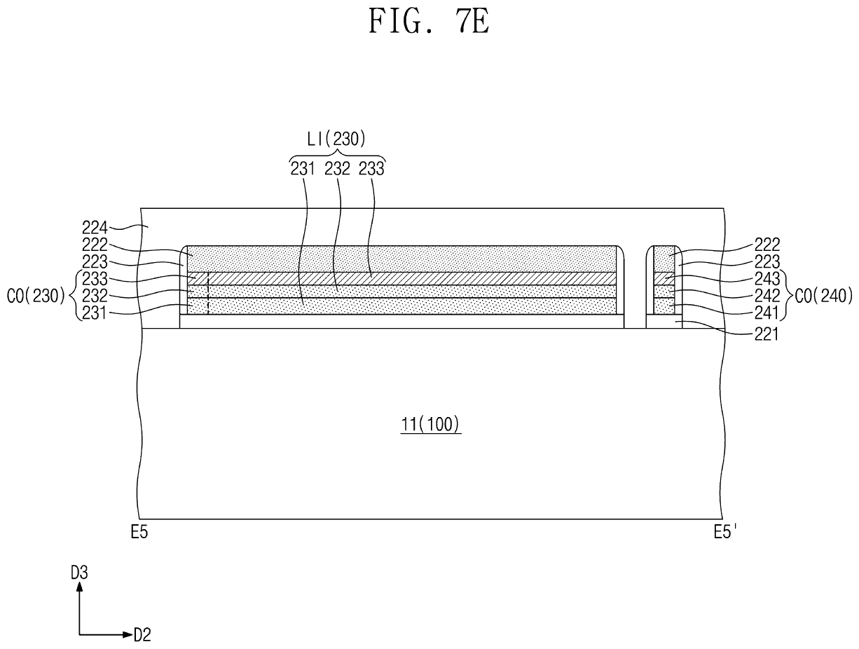

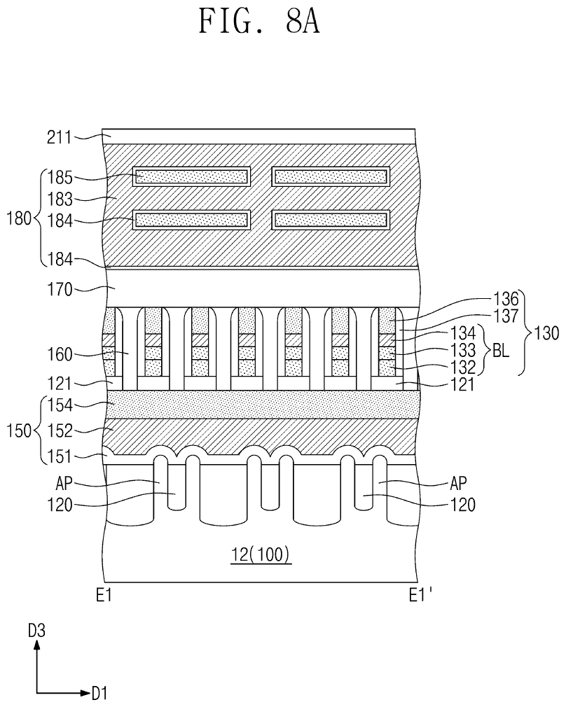

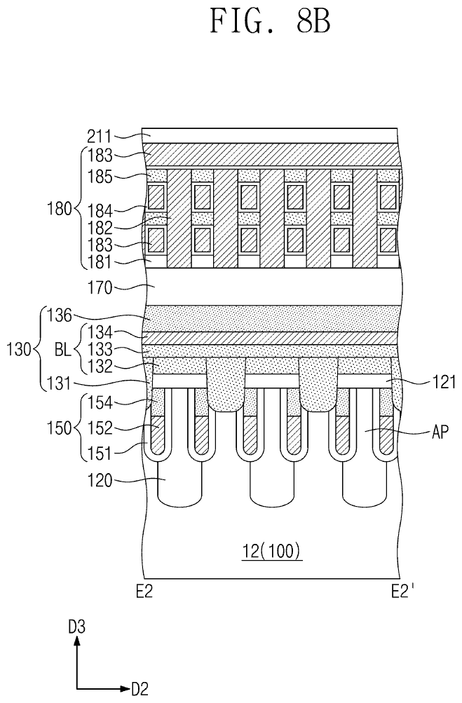

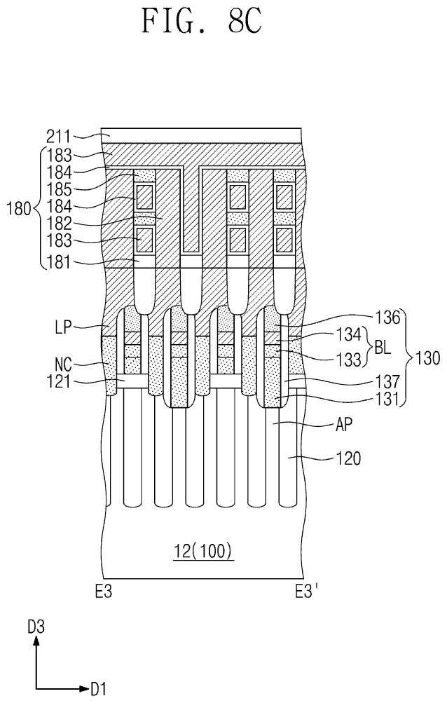

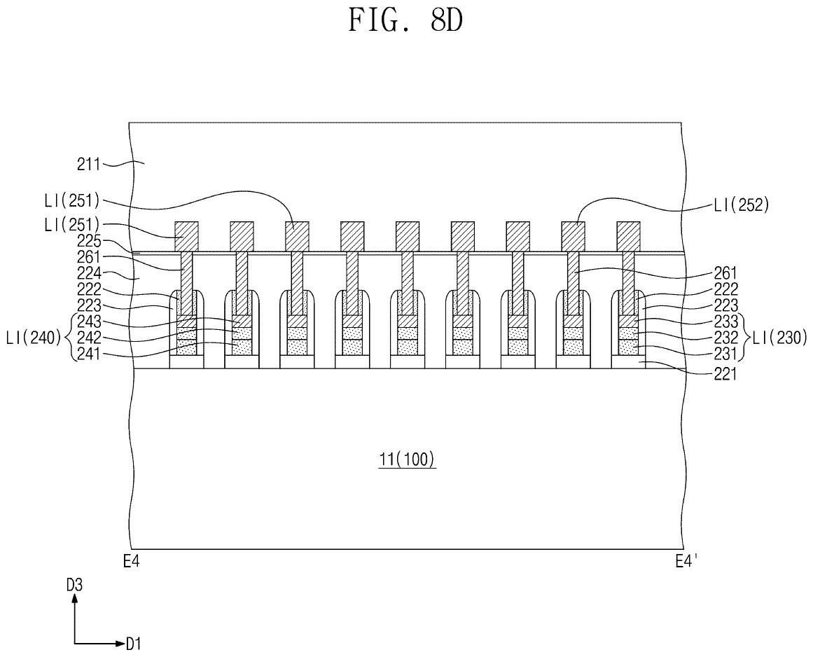

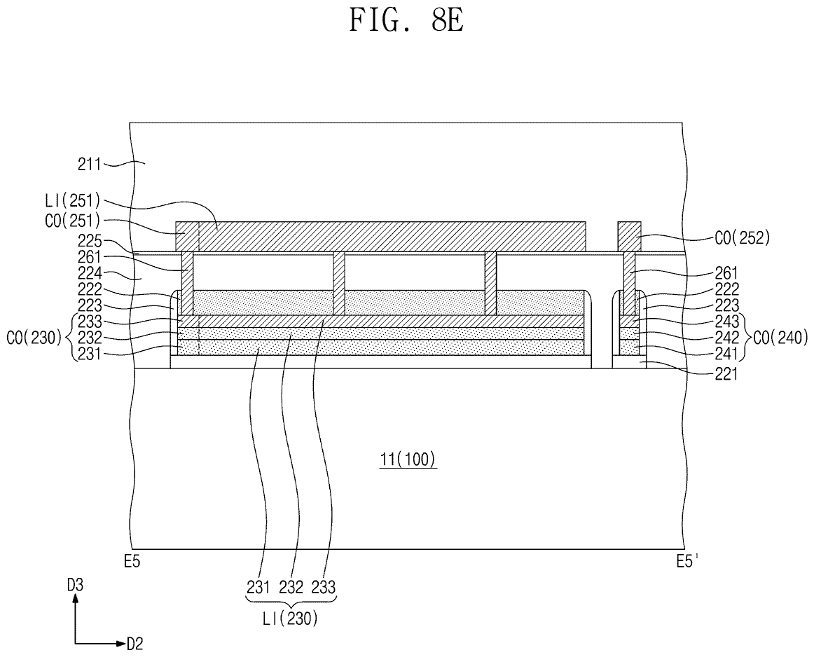

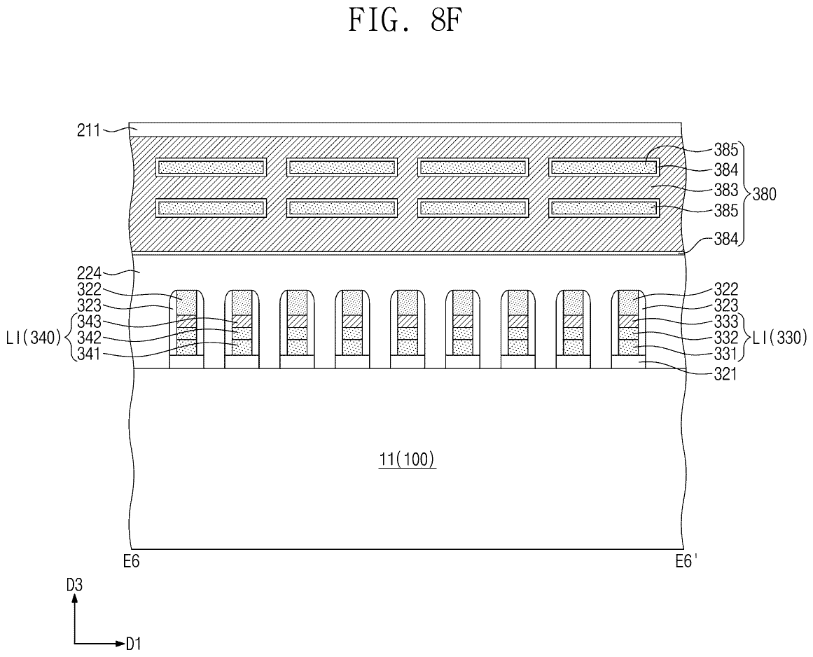

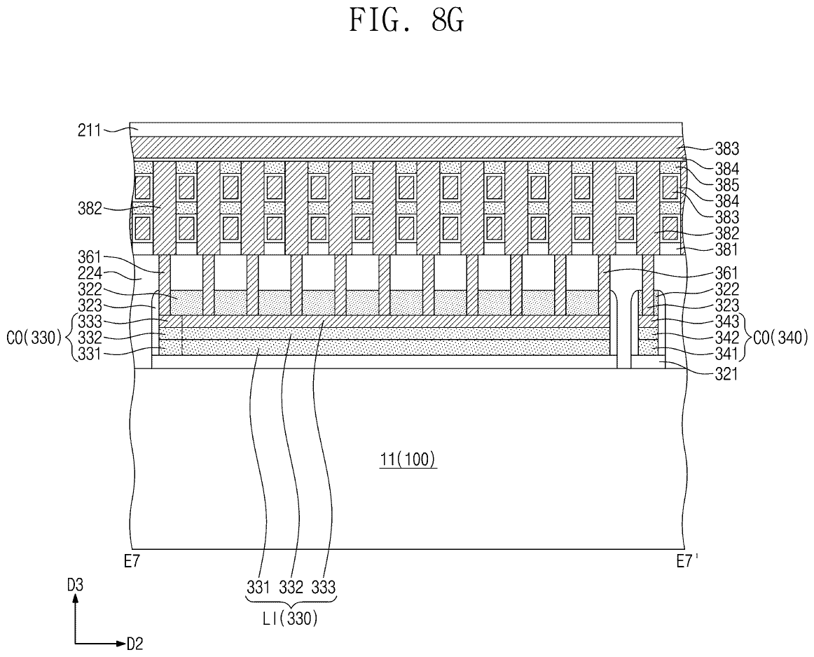

FIGS. 7A, 7B, 7C, 7D, 7E, 8A, 8B, 8C, 8D, 8E, 8F, and 8G are diagrams illustrating a method of fabricating a semiconductor device, according to an embodiment of the inventive concept.

Referring to FIGS. 7A, 7B, 7C, 7D, and 7E, the active patterns AP may be formed. The device isolation layer 120 may be formed. The gate structures 150 may be formed. The peripheral insulating patterns 221 and the power insulating patterns 321 (e.g., of FIGS. 6B and 6C) may be formed at the same time. The bit line contacts 131 may be formed.

The first lower peripheral electrode 230, the second lower peripheral electrode 240, the first lower power electrode 330 (e.g., of FIGS. 6B and 6C), the second lower power electrode 340 (e.g., of FIGS. 6B and 6C), and the bit line BL may be formed at the same time. The bit line capping layer 136, the peripheral capping layer 222, and the power capping layer 322 (e.g., of FIGS. 6B and 6C) may be formed at the same time. The bit line spacer 137, the peripheral spacer 223, and the power spacer 323 (e.g., of FIGS. 6B and 6C) may be formed at the same time.

The node contact NC, the landing pad LP, the insulating fence 160, and the separation structure 170 may be formed. The lower insulating layer 224 may be formed.

Referring to FIGS. 8A, 8B, 8C, 8D, 8E, 8F, and 8G, the cell etch stop layer 181 and the power etch stop layer 381 may be formed at the same time. The lower cell electrode 182 and the third lower power electrode 382 may be formed at the same time. The cell supporters 185 and the power supporters 385 may be formed at the same time. The cell capacitor insulating layer 184, the power capacitor insulating layer 384, and the interlayer insulating layer 225 may be formed at the same time. The second vias 261 and the fifth vias 361 may be formed at the same time. The upper cell electrode 183, the fourth lower power electrode 383, the third lower peripheral electrode 251, and the fourth lower peripheral electrode 252 may be formed at the same time. The first upper insulating layer 211 may be formed.

Referring to FIGS. 4A to 6C, the second to eighth upper insulating layers 212 to 218 may be formed. The first to fourth conductive lines 191 to 194, the first to eighth upper peripheral electrodes 271 to 278, and the first to eighth upper power electrodes 371 to 378 may be formed. The first vias 195, the third vias 262, the fourth vias 263, and the sixth vias 362 may be formed.

The first conductive line 191, the first and second upper peripheral electrodes 271 and 272, and the first and second upper power electrodes 371 and 372 may be formed at the same time. The second conductive line 192, the third and fourth upper peripheral electrodes 273 and 274, and the third and fourth upper power electrodes 373 and 374 may be formed at the same time. The third conductive line 193, the fifth and sixth upper peripheral electrodes 275 and 276, and the fifth and sixth upper power electrodes 375 and 376 may be formed at the same time. The fourth conductive line 194, the seventh and eighth upper peripheral electrodes 277 and 278, and the seventh and eighth upper power electrodes 377 and 378 may be formed at the same time.

In the present specification, “A and B are formed simultaneously or at the same time” may mean that A and B are formed through the same process.

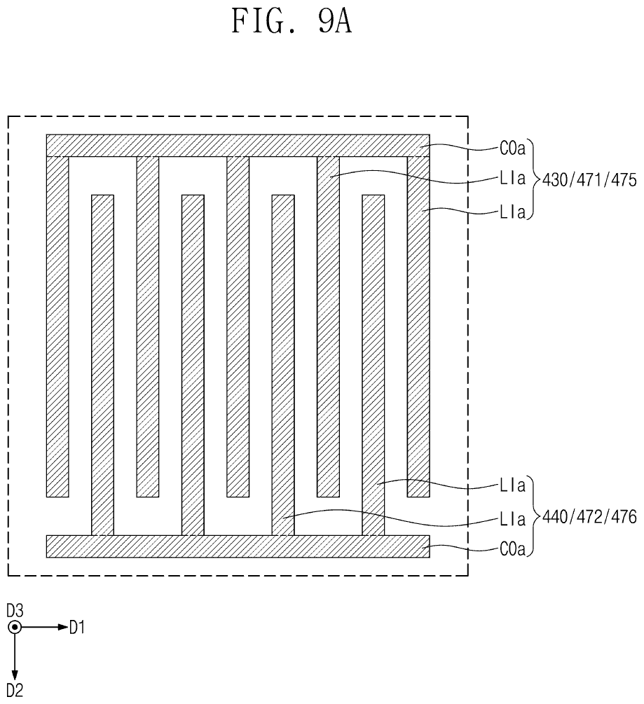

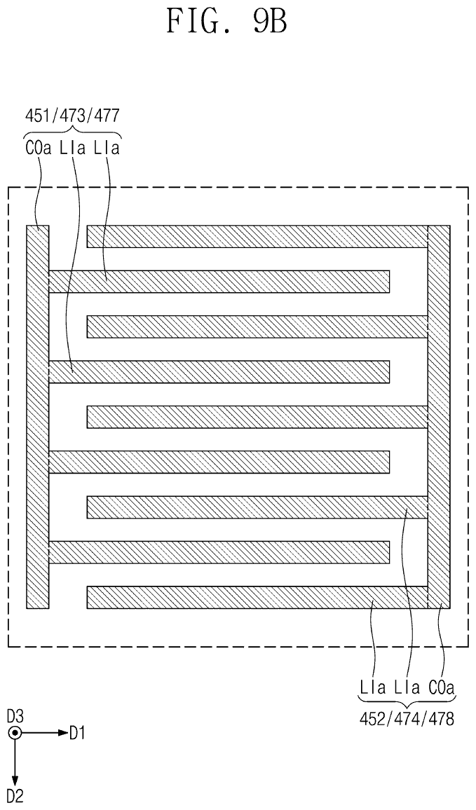

FIGS. 9A and 9B are enlarged plan views illustrating peripheral electrodes of a semiconductor device according to an embodiment of the inventive concept. Except for the features to be described below, the semiconductor device of FIGS. 9A and 9B may be the same as or similar to the semiconductor device described with reference to FIG. 3 to 6C.

Referring to FIGS. 9A and 9B, each of first and second lower peripheral electrodes 430 and 440, and first, second, fifth and sixth upper peripheral electrodes 471, 472, 475, and 476 may include line portions LIa extending lengthwise in the second direction D2 and a connecting portion COa extending lengthwise in the first direction D1. Each of third and fourth lower peripheral electrodes 451 and 452 and third, fourth, seventh and eighth upper peripheral electrodes 473, 474, 477, and 478 may include line portions LIa extending lengthwise in the first direction D1 and a connecting portion COa extending lengthwise in the second direction D2.

First to eighth lower power electrodes may have a structure the same as or similar to a structure of the first to eighth lower peripheral electrodes 471 to 478.

In the semiconductor device according to an embodiment of the inventive concept, the line portions LIa of the peripheral electrodes (e.g., the second and fourth lower peripheral electrodes 440 and 452), which are adjacent to each other in the third direction D3, may be provided to cross each other. Thus, the capacitance of the peripheral capacitor structure may be increased.

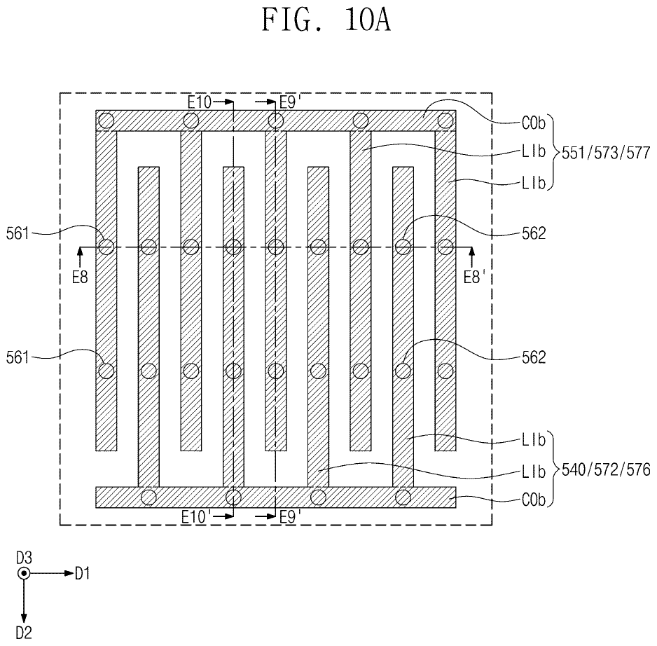

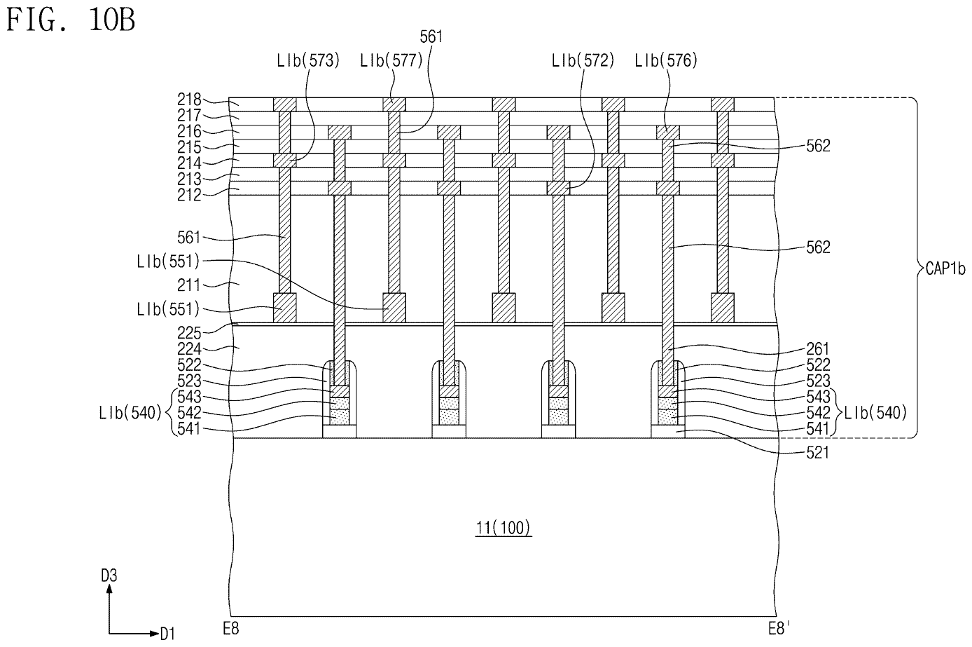

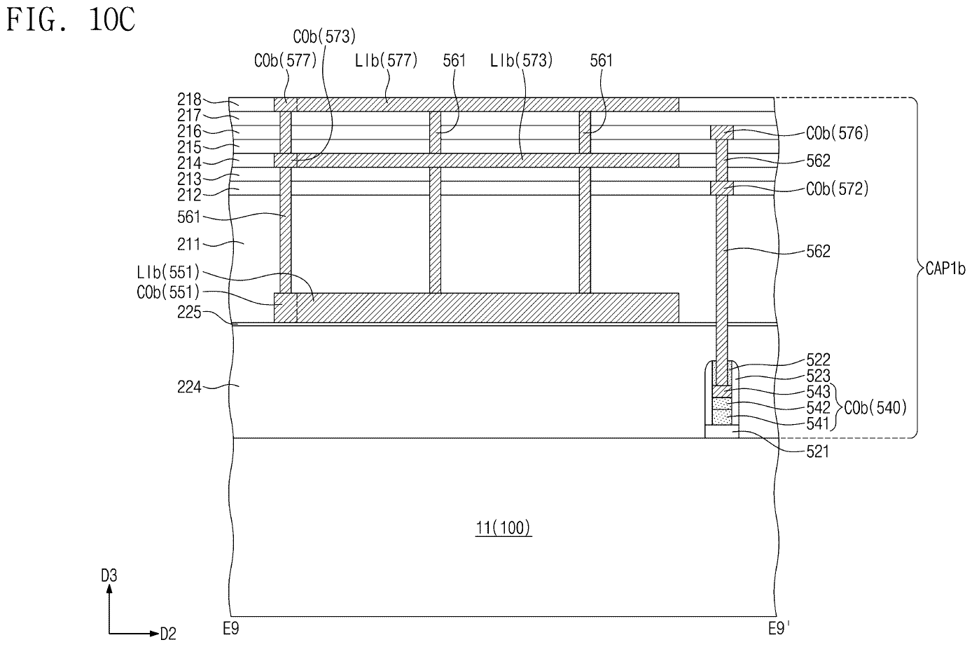

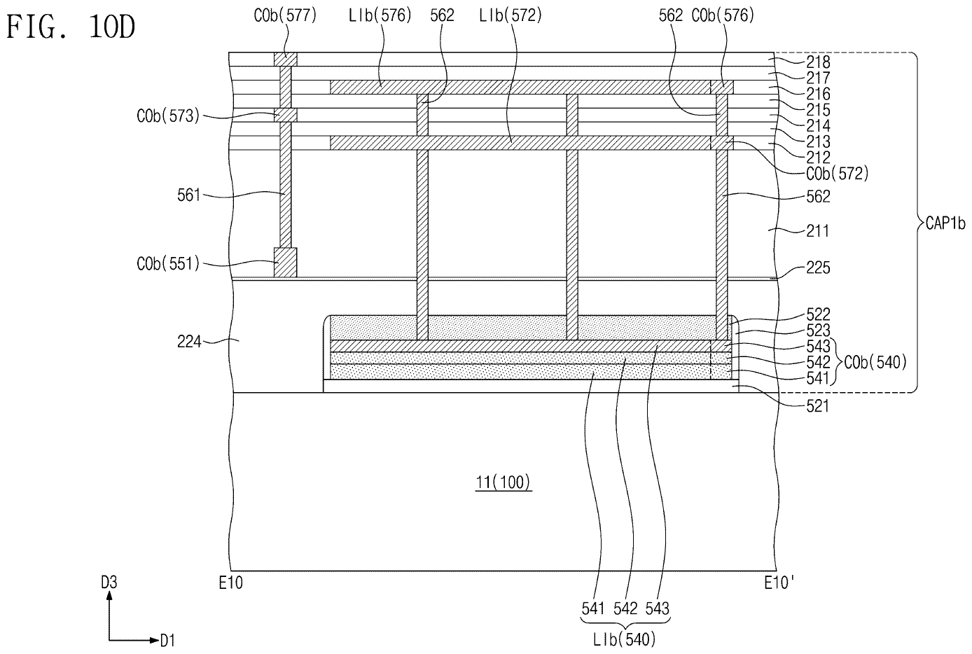

FIG. 10A is an enlarged plan view illustrating a semiconductor device according to an embodiment of the inventive concept. FIG. 10B is a sectional view taken along a line E8-E8′ of FIG. 10A. FIG. 10C is a sectional view taken along a line E9-E9′ of FIG. 10A. FIG. 10D is a sectional view taken along a line E10-E10′ of FIG. 10A. Except for the features to be described below, the semiconductor device of FIGS. 10A, 10B, 10C, and 10D may be the same as or similar to the semiconductor device described with reference to FIG. 3 to 6C.

Referring to FIGS. 10A, 10B, 10C, and 10D, a peripheral capacitor structure CAP1b of the semiconductor device may include a first lower peripheral electrode 540, a second lower peripheral electrode 551, a first upper peripheral electrode 572, a second upper peripheral electrode 573, a third upper peripheral electrode 576, and a fourth upper peripheral electrode 577.

A first lower peripheral electrode 540 may be provided on a peripheral insulating pattern 521. The first lower peripheral electrode 540 may include a first electrode layer 541, a second electrode layer 542, and a third electrode layer 543. A peripheral spacer 523 may be provided to be in contact with a side surface of the first lower peripheral electrode 540. A peripheral capping layer 522 may be provided to be in contact with a top surface of the first lower peripheral electrode 540.

The first lower peripheral electrode 540, the first upper peripheral electrode 572, and the third upper peripheral electrode 576 may be overlapped with each other in the third direction D3. The second lower peripheral electrode 551, the second upper peripheral electrode 573, and the fourth upper peripheral electrode 577 may be overlapped with each other in the third direction D3. The first lower peripheral electrode 540, the first upper peripheral electrode 572, and the third upper peripheral electrode 576 may not be overlapped with the second lower peripheral electrode 551, the second upper peripheral electrode 573, and the fourth upper peripheral electrode 577 in the third direction D3.

The first lower peripheral electrode 540, the first upper peripheral electrode 572, and the third upper peripheral electrode 576 may be electrically connected to each other. The second lower peripheral electrode 551, the second upper peripheral electrode 573, and the fourth upper peripheral electrode 577 may be electrically connected to each other.

Each of the first lower peripheral electrode 540, the first upper peripheral electrode 572, and the third upper peripheral electrode 576 may be electrically disconnected (e.g., electrically insulated) from the second lower peripheral electrode 551, the second upper peripheral electrode 573, and the fourth upper peripheral electrode 577. Each of the second lower peripheral electrode 551, the second upper peripheral electrode 573, and the fourth upper peripheral electrode 577 may be electrically disconnected (e.g., electrically insulated) from the first lower peripheral electrode 540, the first upper peripheral electrode 572, and the third upper peripheral electrode 576.

The first lower peripheral electrode 540, the first upper peripheral electrode 572, and the third upper peripheral electrode 576 may be disposed at different levels from the second lower peripheral electrode 551, the second upper peripheral electrode 573, and the fourth upper peripheral electrode 577, respectively.

Each of the first lower peripheral electrode 540, the second lower peripheral electrode 551, the first upper peripheral electrode 572, the second upper peripheral electrode 573, the third upper peripheral electrode 576, and the fourth upper peripheral electrode 577 may include line portions LIb extending lengthwise in the second direction D2 and a connecting portion COb electrically connecting the line portions LIb.

First vias 561 may be provided to electrically connect the second lower peripheral electrode 551, the second upper peripheral electrode 573, and the fourth upper peripheral electrode 577. Second vias 562 may be provided to electrically connect the first lower peripheral electrode 540, the first upper peripheral electrode 572, and the third upper peripheral electrode 576.

In the semiconductor device according to an embodiment of the inventive concept, the peripheral electrodes (e.g., the first and second lower peripheral electrodes 540 and 551), which are adjacent to each other in the third direction D3, may be electrically disconnected (e.g., electrically insulated) from each other, and thus, the capacitance of the peripheral capacitor structure CAP1b may be increased.

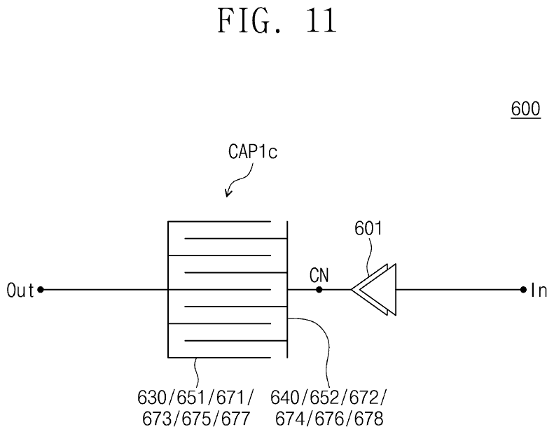

FIG. 11 is a view illustrating a semiconductor device according to an embodiment of the inventive concept. Except for the features to be described below, the semiconductor device of FIG. 11 may be the same as or similar to the semiconductor device described with reference to FIG. 3 to 6C.

Referring to FIG. 11, the circuit structure 14 of FIG. 3 may include an AC coupled pre-emphasis circuit 600. The AC coupled pre-emphasis circuit 600 may be configured to control frequency components of signals, which are received through an input terminal In, and to output signals including the controlled frequency components to an output terminal Out. The AC coupled pre-emphasis circuit 600 may include an equalizer 601 and a peripheral capacitor structure CAP1c. The equalizer 601 may be placed between and coupled to the input terminal In and a connection node CN. A first lower peripheral electrode 630, a third lower peripheral electrode 651, a first upper peripheral electrode 671, a third upper peripheral electrode 673, a fifth upper peripheral electrode 675, and a seventh upper peripheral electrode 677 of the peripheral capacitor structure CAP1c may be coupled to the output terminal Out. A second lower peripheral electrode 640, a fourth lower peripheral electrode 652, a second upper peripheral electrode 672, a fourth upper peripheral electrode 674, a sixth upper peripheral electrode 676, and an eighth upper peripheral electrode 678 of the peripheral capacitor structure CAP1c may be coupled to the connection node CN and may be electrically connected to the equalizer 601.

According to an embodiment of the inventive concept, a semiconductor device may include a peripheral capacitor structure and a power capacitor structure with improved capacitance characteristics.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

While example embodiments of the inventive concept have been particularly shown and described, it will be understood by one of ordinary skill in the art that variations in form and detail may be made therein without departing from the spirit and scope of the attached claims.

What is claimed is:

1. A semiconductor device, comprising:
a substrate including a cell block region and a peripheral region;
a memory cell array on the cell block region; and
a peripheral capacitor structure on the peripheral region,
wherein the memory cell array comprises:
an active pattern;
a bit line structure on the active pattern;
a cell capacitor structure electrically connected to the active pattern; and
a cell conductive structure on the cell capacitor structure,
wherein the peripheral capacitor structure comprises:
a first lower peripheral electrode placed at a level lower than the cell conductive structure;
a second lower peripheral electrode spaced apart from the first lower peripheral electrode;
a first upper peripheral electrode placed at a level higher than the first and second lower peripheral electrodes; and
a second upper peripheral electrode spaced apart from the first upper peripheral electrode.

2. The semiconductor device of claim 1, wherein the bit line structure comprises:
a bit line contact on the active pattern;
a bit line on the bit line contact; and
a bit line capping layer on the bit line,
wherein the first and second lower peripheral electrodes are placed at a level that is lower than the uppermost portion of the bit line capping layer and is higher than the lowermost portion of the bit line contact.

3. The semiconductor device of claim 1, wherein the cell capacitor structure comprises:
a lower cell electrode;
an upper cell electrode spaced apart from the lower cell electrode; and
a cell capacitor insulating layer between the lower cell electrode and the upper cell electrode,
wherein the first and second lower peripheral electrodes are placed at a level that is lower than the uppermost portion of the upper cell electrode and is higher than the bit line structure.

4. The semiconductor device of claim 1, wherein the first lower peripheral electrode and the first upper peripheral electrode are electrically connected to each other, and
the second lower peripheral electrode and the second upper peripheral electrode are electrically connected to each other.

5. The semiconductor device of claim 4, wherein the peripheral capacitor structure further comprises:
a third lower peripheral electrode between the first lower peripheral electrode and the first upper peripheral electrode; and
a fourth lower peripheral electrode between the second lower peripheral electrode and the second upper peripheral electrode,
wherein the third and fourth lower peripheral electrodes are electrically insulated from each other, and
the third and fourth lower peripheral electrodes are placed at a level higher than the bit line structure.

6. The semiconductor device of claim 5, wherein the third lower peripheral electrode is electrically connected to the first lower peripheral electrode and the first upper peripheral electrode, and
the fourth lower peripheral electrode is electrically connected to the second lower peripheral electrode and the second upper peripheral electrode.

7. The semiconductor device of claim 1, wherein the first lower peripheral electrode and the second lower peripheral electrode are placed at different levels from each other.

8. A semiconductor device, comprising:
a substrate including a cell block region and a peripheral region;
a memory cell array on the cell block region; and
a peripheral capacitor structure on the peripheral region,
wherein the memory cell array comprises:
an active pattern;
a bit line structure on the active pattern; and
a cell capacitor structure electrically connected to the active pattern,
wherein the peripheral capacitor structure comprises:
a first lower peripheral electrode and a second lower peripheral electrode placed at a level lower than the cell capacitor structure; and
a third lower peripheral electrode and a fourth lower peripheral electrode placed at a level higher than the bit line structure.

9. The semiconductor device of claim 8, wherein the bit line structure comprises:
a bit line contact on the active pattern;
a bit line on the bit line contact; and
a bit line capping layer on the bit line,
wherein the first lower peripheral electrode and the second lower peripheral electrode comprise the same material as the bit line.

10. The semiconductor device of claim 9, wherein the bit line comprises:
a first conductive layer; and
a second conductive layer on the first conductive layer,
wherein each of the first and second lower peripheral electrodes comprises:
a first electrode layer; and
a second electrode layer on the first electrode layer,
wherein the first conductive layer and the first electrode layer comprise poly silicon, and the second conductive layer and the second electrode layer comprise a metallic material.

11. The semiconductor device of claim 9, wherein the bit line structure further comprises a bit line spacer in contact with a side surface of the bit line,
wherein the peripheral capacitor structure further comprises:
a first peripheral spacer in contact with a side surface of the first lower peripheral electrode;
a second peripheral spacer in contact with a side surface of the second lower peripheral electrode;
a first peripheral capping layer in contact with a top surface of the first lower peripheral electrode; and
a second peripheral capping layer in contact with a top surface of the second lower peripheral electrode,
wherein the bit line spacer, the first peripheral spacer, and the second peripheral spacer comprise the same material, and
the bit line capping layer, the first peripheral capping layer, and the second peripheral capping layer comprise the same material.

12. The semiconductor device of claim 8, wherein the cell capacitor structure comprises:
a lower cell electrode;
an upper cell electrode spaced apart from the lower cell electrode; and
a cell capacitor insulating layer between the lower cell electrode and the upper cell electrode,
wherein the third and fourth lower peripheral electrodes comprise the same material as the upper cell electrode.

13. The semiconductor device of claim 8, wherein the first lower peripheral electrode includes first line portions, which are arranged to be spaced apart from each other in a first direction, and a first connecting portion, which is provided to electrically connect the first line portions,
the second lower peripheral electrode comprises second line portions, which are arranged to be spaced apart from each other in the first direction, and a second connecting portion, which is provided to electrically connect the second line portions, and
the first and second line portions are alternately arranged to be spaced apart from each other in the first direction.

14. The semiconductor device of claim 13, wherein the first and second line portions are disposed between the first and second connecting portions.

15. The semiconductor device of claim 13, wherein the third lower peripheral electrode comprises third line portions, which are arranged to be spaced apart from each other in a second direction crossing the first direction, and a third connecting portion, which is provided to electrically connect the third line portions,
the fourth lower peripheral electrode comprises fourth line portions arranged to be spaced apart from each other in the second direction, and a fourth connecting portion, which is provided to electrically connect the fourth line portions, and
the third and fourth line portions are alternately arranged to be spaced apart from each other in the second direction.

16. The semiconductor device of claim 8, further comprising a power capacitor structure on the peripheral region,
wherein the power capacitor structure comprises:
a first lower power electrode placed at a level lower than the cell capacitor structure;
an upper power electrode placed at a level higher than the cell capacitor structure;
a second lower power electrode electrically connected to the first lower power electrode;
a third lower power electrode electrically connected to the upper power electrode; and
a power capacitor insulating layer between the second lower power electrode and the third lower power electrode.

17. The semiconductor device of claim 16, wherein the cell capacitor structure comprises:
a lower cell electrode;
an upper cell electrode spaced apart from the lower cell electrode; and
a cell capacitor insulating layer between the lower cell electrode and the upper cell electrode,
wherein the second lower power electrode comprises the same material as the lower cell electrode, and
the third lower power electrode comprises the same material as the upper cell electrode.

18. The semiconductor device of claim 16, wherein the power capacitor structure further comprises a power supporter enclosing the second lower power electrode, and
the power supporter is in contact with the second lower power electrode and the power capacitor insulating layer and is spaced apart from the third lower power electrode.

19. A semiconductor device, comprising:
a substrate including a cell block region and a peripheral region;
a memory cell array on the cell block region; and
a peripheral capacitor structure on the peripheral region,
wherein the memory cell array comprises:
an active pattern;
a gate structure on the active pattern;
a bit line contact on the active pattern;
a bit line on the bit line contact;
a bit line spacer in contact with a side surface of the bit line;
a bit line capping layer in contact with a top surface of the bit line;
a node contact on the active pattern;
a landing pad on the node contact;
a lower cell electrode on the landing pad;
a cell supporter enclosing the lower cell electrode;
an upper cell electrode spaced apart from the lower cell electrode and the cell supporter; and
a cell capacitor insulating layer between the lower cell electrode and the upper cell electrode,
wherein the peripheral capacitor structure comprises:
first and second lower peripheral electrodes placed at a level lower than the lower cell electrode;
third and fourth lower peripheral electrodes placed at a level higher than the bit line capping layer; and
first and second upper peripheral electrodes placed at a level higher than the upper cell electrode,
wherein the first and second lower peripheral electrodes comprise the same material as the bit line, and
the third and fourth lower peripheral electrodes comprise the same material as the upper cell electrode.

20. The semiconductor device of claim 19, wherein a level of top surfaces of the first and second lower peripheral electrodes is equal to a level of the top surface of the bit line, and
a level of bottom surfaces of the first and second lower peripheral electrodes is equal to a level of a bottom surface of the bit line.
